(19) United States
(12) Patent Application Publication
(10) Pub. No.: US 2025/0212574 A1
(43) Pub. Date: Jun. 26, 2025

(54) PIXEL AND DISPLAY DEVICE INCLUDING THE SAME

(71) Applicant: Samsung Display Co., LTD., Yongin-si (KR)

(72) Inventors: Chang Il TAE, Yongin-si (KR); Kang Young LEE, Yongin-si (KR); Hyung Il JEON, Yongin-si (KR); Jin Woo CHOI, Yongin-si (KR)

(21) Appl. No.: 18/781,655

(22) Filed: Jul. 23, 2024

(30) Foreign Application Priority Data
Dec. 21, 2023 (KR) 10-2023-0188387

(51) Int. Cl. H01L 33/62; H01L 25/16

(52) U.S. Cl. CPC H10H 20/857; H01L 25/167

(57) ABSTRACT

A display device according to one or more embodiments includes a first pixel in a display area, and including a first pixel electrode, a first common electrode spaced apart from the first pixel electrode, a first light-emitting element connected between the first pixel electrode and the first common electrode, and a second light-emitting element connected in parallel with the first light-emitting element between the first pixel electrode and the first common electrode, and having a threshold voltage that is lower than a threshold voltage of the first light-emitting element.

### CROSS-REFERENCE TO RELATED APPLICATION

The present application claims priority to, and the benefit of, Korean Patent Application No. 10-2023-0188387, filed on Dec. 21, 2023, in the Korean Intellectual Property Office, the entire disclosure of which is incorporated herein by reference.

### BACKGROUND

### 1. Field

The present disclosure relates to a pixel and a display device including the same.

### 2. Description of the Related Art

With the advance of information-oriented society, more and more demands are placed on display devices for displaying images in various ways. Along with this trend, various types of display devices including a light-emitting display device are being developed.

A light-emitting display device may use light-emitting elements, such as organic light-emitting diodes or micro light-emitting diodes (hereinafter referred to as “micro light-emitting elements”) as light sources for pixels. To reduce power consumption of the light-emitting display device, a high-efficiency light-emitting element may be used. However, it may be difficult to precisely control the luminance of a low grayscale by using the high-efficiency light-emitting element. Accordingly, the image quality of the display device may deteriorate.

### SUMMARY

Aspects of the present disclosure provide a pixel capable of improving image quality while reducing power consumption, and a display device including the same.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a first pixel in a display area, and including a first pixel electrode, a first common electrode spaced apart from the first pixel electrode, a first light-emitting element connected between the first pixel electrode and the first common electrode, and a second light-emitting element connected in parallel with the first light-emitting element between the first pixel electrode and the first common electrode, and having a threshold voltage that is lower than a threshold voltage of the first light-emitting element.

A size of the first light-emitting element may be different from a size of the second light-emitting element.

The size of the first light-emitting element may be larger than the size of the second light-emitting element.

A luminous efficiency of the first light-emitting element may be higher than a luminous efficiency of the second light-emitting element.

The first pixel electrode and the first common electrode might not overlap each other in a thickness direction of the first light-emitting element and the second light-emitting element, wherein a portion of the first light-emitting element and a portion of the second light-emitting element are above the first pixel electrode, and wherein another portion of the first light-emitting element and another portion of the second light-emitting element are above the first common electrode.

The first pixel electrode and the first common electrode might not overlap each other in a thickness direction of the first light-emitting element and the second light-emitting element, wherein the first light-emitting element and the second light-emitting element are above the first pixel electrode, and wherein the first common electrode is above the first light-emitting element and the second light-emitting element.

The first pixel electrode may include a first sub-pixel electrode and a second sub-pixel electrode separated from each other and electrically connected to each other.

The first light-emitting element and the second light-emitting element may be above the first sub-pixel electrode and the second sub-pixel electrode, respectively.

The first common electrode may include a first sub-common electrode and a second sub-common electrode separated from each other and electrically connected to each other.

The first light-emitting element may include a first portion above the first sub-pixel electrode, and a second portion extending from the first portion and above the first sub-common electrode, wherein the second light-emitting element includes a first portion above the second sub-pixel electrode, and a second portion extending from the first portion and above the second sub-common electrode.

The first light-emitting element and the second light-emitting element may include a first contact electrode above the first pixel electrode, a first semiconductor layer above the first contact electrode, a light-emitting layer above the first semiconductor layer, and a second semiconductor layer above the light-emitting layer, and electrically connected to the first common electrode.

The first light-emitting element and the second light-emitting element may further include a second contact electrode between the second semiconductor layer and the first common electrode.

The first pixel may further include a third light-emitting element connected in series with the second light-emitting element between the first pixel electrode and the first common electrode, wherein a threshold voltage of the third light-emitting element is lower than the threshold voltage of the first light-emitting element.

The threshold voltage of the third light-emitting element may be equal to the threshold voltage of the second light-emitting element.

The first pixel may further include a fourth light-emitting element connected in series with the first light-emitting element between the first pixel electrode and the first common electrode, wherein a threshold voltage of the fourth light-emitting element is higher than the threshold voltage of the second light-emitting element.

The threshold voltage of the fourth light-emitting element may be equal to the threshold voltage of the first light-emitting element.

The display device may further include a second pixel in the display area and including more light-emitting elements than the first pixel, wherein two of the light-emitting elements of the second pixel are connected in parallel and have different respective threshold voltages.

The first pixel and the second pixel may be configured to emit light of different respective colors.

According to an aspect of the present disclosure, there is provided a pixel including a pixel electrode, a common electrode spaced apart from the pixel electrode, a first light-emitting element connected between the pixel electrode and the common electrode, and a second light-emitting element connected in parallel with the first light-emitting element between the pixel electrode and the common electrode, and having a threshold voltage that is lower than a threshold voltage of the first light-emitting element.

The pixel may further include a third light-emitting element connected in series with the second light-emitting element between the pixel electrode and the common electrode, wherein a threshold voltage of the third light-emitting element is lower than the threshold voltage of the first light-emitting element.

The pixel according to embodiments includes a first light-emitting element and a second light-emitting element that are connected in parallel between a pixel electrode and a common electrode, and that have different threshold voltages. The display device according to embodiments includes the pixel.

According to embodiments, the luminance of the pixel according to a low grayscale data signal may be appropriately controlled while power consumption of the display device is reduced. Accordingly, the low grayscale expression performance of the pixel may be increased, and the image quality of the display device may be improved.

However, aspects according to the embodiments of the present disclosure are not limited to those described above, and various other aspects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating a display device according to one or more embodiments;

FIG. 2 is a plan view illustrating a display panel according to one or more embodiments;

FIG. 3 is a block diagram illustrating a display device according to one or more embodiments;

FIG. 4 is a circuit diagram illustrating a sub-pixel according to one or more embodiments;

FIG. 5 is a circuit diagram illustrating a sub-pixel according to one or more embodiments;

FIG. 6 is a circuit diagram illustrating a sub-pixel according to one or more embodiments;

FIG. 7 is a circuit diagram illustrating a sub-pixel according to one or more embodiments;

FIG. 8 is a plan view illustrating sub-pixels according to one or more embodiments;

FIG. 9 is a plan view showing sub-pixels according to one or more embodiments;

FIG. 10 is a plan view showing sub-pixels according to one or more embodiments;

FIG. 11 is a plan view showing sub-pixels according to one or more embodiments;

FIG. 12 is a plan view showing sub-pixels according to one or more embodiments;

FIG. 13 is a cross-sectional view illustrating a display panel according to one or more embodiments;

FIG. 14 is a cross-sectional view showing area A1 of FIG. 13 in detail;

FIG. 15 is a plan view showing sub-pixels according to one or more embodiments;

FIG. 16 is a cross-sectional view illustrating a display panel according to one or more embodiments;

FIG. 17 is a diagram illustrating a virtual reality device including a display device according to one or more embodiments;

FIG. 18 is a diagram illustrating a smart device including a display device according to one or more embodiments;

FIG. 19 is a diagram illustrating a dashboard of an automobile and a center fascia including display devices according to one or more embodiments; and

FIG. 20 is a diagram illustrating a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

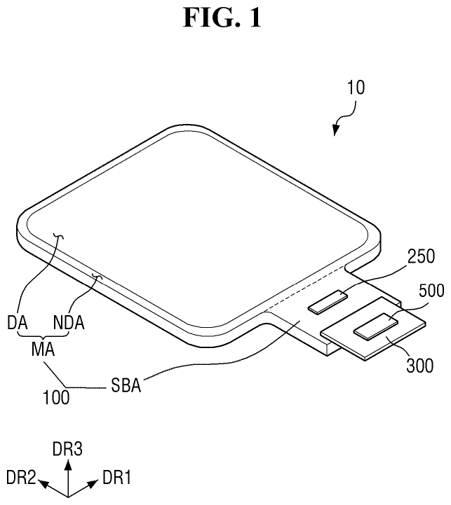

FIG. 1 is a perspective view illustrating a display device according to one or more embodiments.

Referring to FIG. 1, a display device 10 is a device for displaying a moving image or a still image. The display device 10 may be used as a display screen of various devices, such as a television, a laptop computer, a monitor, a billboard, and an Internet-of-Things (IOT) device, as well as portable electronic devices, such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may be a light-emitting display device, such as an organic light-emitting display using an organic light-emitting diode, a quantum dot light-emitting display including a quantum dot light-emitting layer, an inorganic light-emitting display including an inorganic semiconductor, and a micro light-emitting display using a micro or nano light-emitting diode (LED). In the following description, it is assumed that the display device 10 is a micro light-emitting display device, but the embodiments are not limited thereto. Meanwhile, for simplicity of description, an ultra-small light-emitting diode is referred to hereafter as a light-emitting element. However, the type of light-emitting elements that may be applied to embodiments is not limited to micro light-emitting diodes.

The display device 10 includes a display panel 100, a display-driving circuit 250, a circuit board 300, and a power supply circuit 500.

The display panel 100 may have a rectangular or square planar shape with sides extending in a first direction DR1, and sides extending in a second direction DR2 crossing the first direction DR1. The corner where the sides in the first direction DR1 and the sides in the second direction DR2 meet may be rounded to have a curvature (e.g., predetermined curvature), or may be right-angled. The planar shape of the display panel 100 is not limited to a quadrilateral shape. For example, the display panel 100 may have a different planar shape, such as a polygonal shape, a circular shape, or an elliptical shape. The display panel 100 may be formed to be flat, but is not limited thereto. For example, the display panel 100 may include a curved portion formed at left and right ends and having a constant curvature or a varying curvature. In one or more embodiments, the display panel 100 may be formed flexibly such that it may be curved, bent, folded, or rolled.

A substrate SUB of the display panel 100 may include a main region MA and a sub-region SBA.

The main region MA may include a display area DA for displaying an image, and a non-display area NDA that is a peripheral area of the display area DA. The display area DA may include pixels for displaying an image. In one or more embodiments, each pixel may include a first sub-pixel that emits first light, a second sub-pixel that emits second light, and a third sub-pixel that emits third light.

The sub-region SBA may protrude from one side of the main region MA in the second direction DR2. Although it is shown in FIG. 1 that the sub-region SBA is unfolded, the sub-region SBA may be bent and arranged on the bottom surface of (e.g., below) the display panel 100. When the sub-region SBA is bent, the main region MA and the sub-region SBA may overlap in a third direction DR3, which is the thickness direction of the display panel 100. The display-driving circuit 250 may be arranged in the sub-region SBA.

The display-driving circuit 250 may generate signals and voltages for driving the display panel 100. The display-driving circuit 250 may be formed as an integrated circuit (IC), and may be attached onto the display panel 100 by a chip-on-glass (COG) method, a chip-on-plastic (COP) method, or an ultrasonic bonding method, but the present disclosure is not limited thereto. For example, the display-driving circuit 250 may be attached onto the circuit board 300 by a chip-on-film (COF) method.

The circuit board 300 may be attached to the sub-region SBA of the display panel 100. As an example, the circuit board 300 may be attached to pads of the display panel 100 positioned at one end of the sub-region SBA. Thus, the circuit board 300 may be electrically connected to the display panel 100 and the display-driving circuit 250. The display panel 100 and the display-driving circuit 250 may receive digital video data, timing signals, and driving voltages through the circuit board 300. The circuit board 300 may be a flexible printed circuit board, a printed circuit board, or a flexible film, such as a chip on film.

The power supply circuit 500 may generate panel-driving voltages according to a power voltage supplied from the outside. The power supply circuit 500 may be formed as an integrated circuit (IC), and may be attached to the circuit board 300 by a COF method.

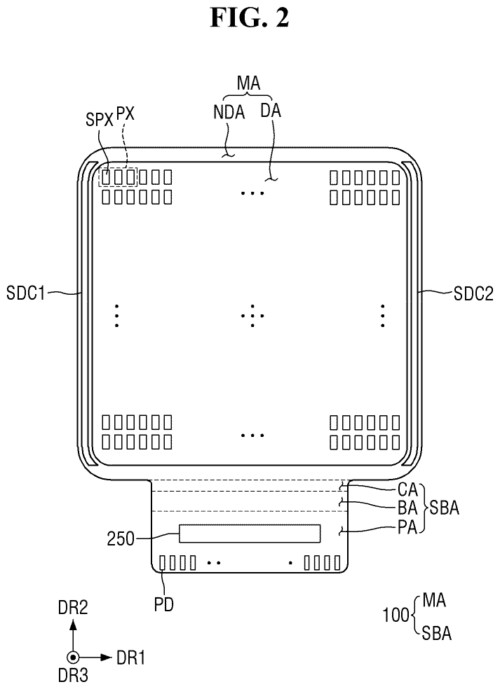

FIG. 2 is a plan view illustrating a display panel according to one or more embodiments. In FIG. 2, the sub-region SBA is illustrated in an unfolded state without being bent.

Referring to FIGS. 1 and 2, the display panel 100 may include the main region MA and the sub-region SBA.

The main region MA may include the display area DA for displaying an image, and the non-display area NDA that is a peripheral area of the display area DA. The display area DA may occupy most of the main region MA. The display area DA may be located at the center of the main region MA.

The display area DA may include unit pixels PX for displaying an image, and each of the unit pixels PX may include a plurality of sub-pixels SPX (or pixels). The unit pixel PX may be defined as a minimum unit sub-pixel group capable of expressing a white grayscale.

The non-display area NDA may be adjacent to the display area DA. The non-display area NDA may be an area outside the display area DA. The non-display area NDA may be located to surround the display area DA (e.g., in plan view). The non-display area NDA may be an edge area of the display panel 100.

A first scan driver SDC1 and a second scan driver SDC2 may be located in the non-display area NDA. The first scan driver SDC1 may be located at one side (for example, left side) of the display panel 100, and the second scan driver SDC2 may be located at the other side (for example, right side) of the display panel 100, but the present disclosure is not limited thereto. Each of the first scan driver SDC1 and the second scan driver SDC2 may be electrically connected to the display-driving circuit 250 through scan fan-out lines. Each of the first scan driver SDC1 and the second scan driver SDC2 may receive scan control signals inputted from the display-driving circuit 250, may generate scan signals in response to the scan control signals, and may output the generated scan signals to scan lines.

The sub-region SBA may protrude from one side of the main region MA in the second direction DR2. The length of the sub-region SBA in the second direction DR2 may be less than the length of the main region MA in the second direction DR2. The length of the sub-region SBA in the first direction DR1 may be substantially equal to or less than the length of the main region MA in the first direction DR1. The sub-region SBA may be bent, and thus a portion of the sub-region SBA may be located below the main region MA. For example, the sub-region SBA may overlap the main region MA in the third direction DR3.

The sub-region SBA may include a connection area CA, a pad area PA, and a bending area BA.

The connection area CA is an area protruding from one side of the main region MA in the second direction DR2. One side of the connection area CA may be in contact with the non-display area NDA of the main region MA, and the other side of the connection area CA may be in contact with the bending area BA.

The pad area PA is an area on which pads PD and the display-driving circuit 250 are located. The display-driving circuit 250 may be attached to driving pads of the pad area PA using a conductive adhesive member, such as an anisotropic conductive film. The circuit board 300 may be attached to the pads PD of the pad area PA using a conductive adhesive member, such as an anisotropic conductive film. One side of the pad area PA may be in contact with the bending area BA.

The bending area BA is an area that can be bent. When the bending area BA is bent, the pad area PA may be located under the connection area CA and the main region MA. The bending area BA may be located between the connection area CA and the pad area PA. One side of the bending area BA may be in contact with the connection area CA, and the other side of the bending area BA may be in contact with the pad area PA.

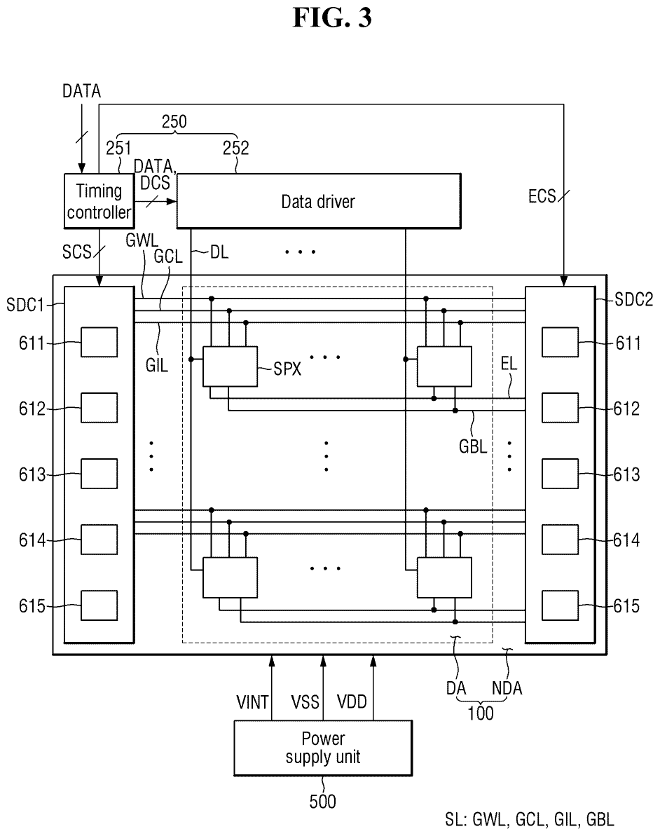

FIG. 3 is a block diagram illustrating a display device according to one or more embodiments.

Referring to FIGS. 1 to 3, the unit pixels PX including each of the sub-pixels SPX, and scan lines SL, emission control lines EL, and data lines DL connected to the sub-pixels SPX may be located in the display area DA.

The sub-pixels SPX may be arranged in a matrix form in the first direction DR1 and the second direction DR2. The scan lines SL and the emission control lines EL may extend in the first direction DR1, and may be arranged in the second direction DR2. The data lines DL may extend in the second direction DR2, and may be arranged along the first direction DR1. The scan lines SL may include write scan lines GWL, control scan lines GCL, initialization scan lines GIL, and bias scan lines GBL located in each pixel row.

Each of the sub-pixels SPX may be connected to one write scan line GWL, one control scan line GCL, one initialization scan line GIL, one bias scan line GBL, one emission control line EL, and one data line DL. For example, each of the sub-pixels SPX may be connected to the write scan line GWL, the control scan line GCL, the initialization scan line GIL, the bias scan line GBL, and the emission control line EL located in each pixel row, and the data line DL located in each pixel column.

Each of the sub-pixels SPX may receive a data signal (e.g., a data voltage) of the data line DL according to a write scan signal supplied through the write scan line GWL, and may cause a light-emitting element to operate according to the data signal.

The first scan driver SDC1, the second scan driver SDC2, and the display-driving circuit 250 may be located in the non-display area NDA.

Each of the first scan driver SDC1 and the second scan driver SDC2 may include a write scan signal output unit 611, a control scan signal output unit 612, an initialization scan signal output unit 613, a bias scan signal output unit 614, and an emission signal output unit 615. Each of the write scan signal output unit 611, the control scan signal output unit 612, the initialization scan signal output unit 613, the bias scan signal output unit 614, and the emission signal output unit 615 may receive a scan-timing control signal SCS from a timing control circuit 251. The write scan signal output unit 611 may generate write scan signals according to the scan-timing control signal SCS of the timing control circuit 251, and may output them sequentially to the write scan lines GWL. The control scan signal output unit 612 may generate control scan signals in response to the scan-timing control signal SCS, and may sequentially output them to the control scan lines GCL. The initialization scan signal output unit 613 may generate initialization scan signals in response to the scan-timing control signal SCS, and may sequentially output them to the initialization scan lines GIL. The bias scan signal output unit 614 may generate bias scan signals according to the scan-timing control signal SCS, and may output them sequentially to the bias scan lines GBL. The emission signal output unit 615 may generate emission control signals according to the scan-timing control signal SCS, and may sequentially output them to the emission control lines EL.

The display-driving circuit 250 may include the timing control circuit 251 and a data-driving circuit 252.

The timing control circuit 251 may receive video data DATA (e.g., digital video data) and timing signals from the outside. The timing control circuit 251 may generate the scan-timing control signal SCS and a data-timing control signal DCS for controlling the display panel 100 in response to the timing signals. The timing control circuit 251 may output the scan-timing control signal SCS to the first scan driver SDC1 and the second scan driver SDC2. The timing control circuit 251 may output the video data DATA and the data-timing control signal DCS to the data-driving circuit 252.

The data-driving circuit 252 may receive the video data DATA and the data-timing control signal DCS from the timing control circuit 251. The data-driving circuit 252 may supply respective data signals (e.g., analog data voltages) to the sub-pixels SPX. For example, the data-driving circuit 252 may convert the video data DATA into analog data voltages in response to the data-timing control signal DCS, and may output them to the data lines DL. The sub-pixels SPX may be selected by the write scan signal of the first scan driver SDC1 and the second scan driver SDC2, and data signals may be supplied to the selected sub-pixels SPX.

The power supply circuit 500 may generate a plurality of panel-driving voltages according to a power voltage from the outside. For example, the power supply circuit 500 may generate a first driving voltage VDD, a second driving voltage VSS, and a third driving voltage VINT, and may supply them to the display panel 100.

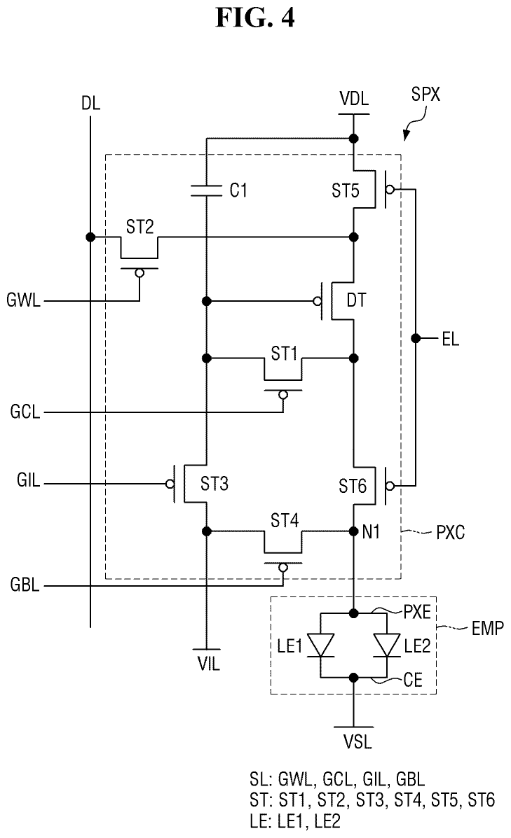

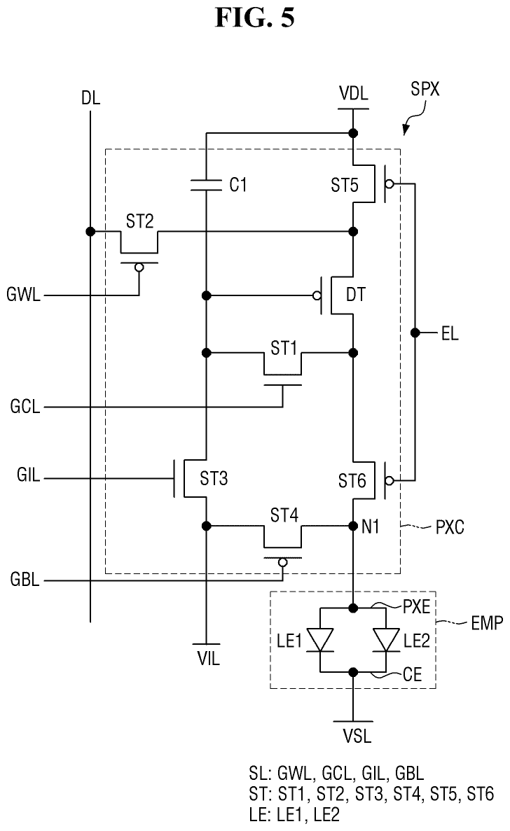

FIG. 4 is a circuit diagram illustrating a sub-pixel according to one or more embodiments. FIG. 5 is a circuit diagram illustrating a sub-pixel according to one or more embodiments. As compared with FIG. 4, FIG. 5 illustrates one or more embodiments in which the types of some transistors are changed.

Referring to FIGS. 4 and 5, the sub-pixel SPX according to one or more embodiments may be connected between a first power line VDL and a second power line VSL, and may include a light-emitting unit EMU including light-emitting elements LE. The sub-pixel SPX may further include a pixel circuit PXC connected to the light-emitting unit EMU. In one or more embodiments, the pixel circuit PXC may be connected between the first power line VDL and the light-emitting unit EMU.

The pixel circuit PXC may be connected to the scan lines SL, the emission control line EL, and the data line DL. For example, the pixel circuit PXC may be connected to the write scan line GWL, the initialization scan line GIL, the control scan line GCL, the bias scan line GBL, the emission control line EL, and the data line DL.

The pixel circuit PXC may include a driving transistor DT, at least one switching transistor ST, and a capacitor C1. In one or more embodiments, the pixel circuit PXC may include first to sixth transistors ST1, ST2, ST3, ST4, ST5, and ST6 as the switching transistor ST. The configuration of the pixel circuit PXC is not limited to the embodiments of FIGS. 4 and 5 and may be changed in various ways.

The driving transistor DT includes a gate electrode, a first electrode, and a second electrode. The driving transistor DT may control a drain-source current (hereinafter referred to as a “driving current”) that flows between the first electrode and the second electrode according to a data signal (e.g., analog data voltage) applied to the gate electrode.

The first transistor ST1 may be connected between the second electrode and the gate electrode of the driving transistor DT, and the gate electrode of the first transistor ST1 may be connected to the control scan line GCL. The first transistor ST1 may operate as a switch according to the control scan signal supplied to the control scan line GCL.

The second transistor ST2 may be connected between the data line DL and the first electrode of the driving transistor DT, and the gate electrode of the second transistor ST2 may be connected to the write scan line GWL. The second transistor ST2 may operate as a switch according to the write scan signal supplied to the write scan line GWL.

The third transistor ST3 may be connected between the gate electrode of the driving transistor DT and the initialization voltage line VIL, and the gate electrode of the third transistor ST3 may be connected to the initialization scan line GIL. The third transistor ST3 may operate as a switch according to the initialization scan signal supplied to the initialization scan line GIL. The third driving voltage VINT may be applied to the initialization voltage line VIL.

The fourth transistor ST4 may be connected between a first node N1 and the initialization voltage line VIL, and the gate electrode of the fourth transistor ST4 may be connected to the bias scan line GBL. The first node N1 may be a node at which the pixel circuit PXC and the light-emitting unit EMU are connected. As an example, the first node N1 may be a node at which the fourth transistor ST4, the sixth transistor ST6, and the pixel electrode PXE (e.g., anode electrode) of the light-emitting unit EMU are connected to each other. The fourth transistor ST4 may operate as a switch according to the bias scan signal supplied to the bias scan line GBL.

The fifth transistor ST5 may be connected between the first power line VDL and the first electrode of the driving transistor DT, and the gate electrode of the fifth transistor ST5 may be connected to the emission control line EL. The fifth transistor ST5 may operate as a switch according to the emission control signal supplied to the emission control line EL. The first driving voltage VDD may be applied to the first power line VDL.

The sixth transistor ST6 may be connected between the second electrode of the driving transistor DT and the first node N1, and the gate electrode of the sixth transistor ST6 may be connected to the emission control line EL. The sixth transistor ST6 may operate as a switch according to the emission control signal supplied to the emission control line EL.

In one or more embodiments, as illustrated in FIG. 4, the driving transistor DT and the first to sixth transistors ST1, ST2, ST3, ST4, ST5, and ST6 may be formed of p-type transistors. For example, each of the driving transistor DT and the first to sixth transistors ST1, ST2, ST3, ST4, ST5, and ST6 may be formed of a p-type MOSFET including an active layer formed of polysilicon.

In one or more embodiments, as illustrated in FIG. 5, the driving transistor DT, the second transistor ST2, the fourth transistor ST4, the fifth transistor ST5, and the sixth transistor ST6 may be formed of p-type transistors, and the first transistor ST1 and the third transistor ST3 may be formed of n-type transistors. As an example, each of the driving transistor DT, the second transistor ST2, the fourth transistor ST4, the fifth transistor ST5, and the sixth transistor ST6 may be formed of a p-type MOSFET including an active layer formed of polysilicon, and each of the first transistor ST1 and the third transistor ST3 may be formed as an n-type MOSFET including an active layer formed of an oxide semiconductor. In one or more embodiments, transistors including active layers formed of polysilicon and transistors including active layers formed of an oxide semiconductor may be located on different layers in the display panel 100.

Alternatively, although not illustrated in FIGS. 4 and 5, the driving transistor DT and the first to sixth transistors ST1, ST2, ST3, ST4, ST5, and ST6 may be formed of n-type transistors. As an example, each of the driving transistor DT and the first to sixth transistors ST1, ST2, ST3, ST4, ST5, and ST6 may be formed of an n-type MOSFET including an active layer formed of an oxide semiconductor.

Depending on the type of transistor, the levels of the gate-on voltage and gate-off voltage of the signal (e.g., each of a scan signal, a data signal, or an emission control signal) applied to the gate electrode of each transistor may be appropriately set or changed. For example, the gate-on voltage of a p-type transistor may be a low level voltage (e.g., gate-low voltage), and the gate-on voltage of an n-type transistor may be a high level voltage (e.g., gate-high voltage).

The capacitor C1 may be connected between the first power line VDL and the gate electrode of the driving transistor DT. The capacitor C1 may be charged with a voltage corresponding to the data signal.

The light-emitting unit EMP may include a plurality of light-emitting elements LE including a first light-emitting element LE1 and a second light-emitting element LE2. The light-emitting elements LE may be connected between the pixel circuit PXC (or the first node N1) and the second power line VSL. For example, the first contact electrodes (or first semiconductor layers) of the light-emitting elements LE may be connected to the pixel circuit PXC through the pixel electrode PXE, and the second contact electrodes (or second semiconductor layers) of the light-emitting elements LE may be connected to the second power line VSL through the common electrode CE (e.g., cathode electrode). The second driving voltage VSS may be applied to the second power line VSL. The second driving voltage VSS may be a voltage at a lower level than the first driving voltage VDD. In one or more embodiments, each light-emitting element LE may be a micro light-emitting diode. The light-emitting unit EMP may emit light with a luminance corresponding to the driving current supplied from the pixel circuit PXC.

In embodiments, the first light-emitting element LE1 and the second light-emitting element LE2 may be connected in parallel between the pixel electrode PXE and the common electrode CE. In addition, the first light-emitting element LE1 and the second light-emitting element LE2 may be elements with different characteristics, and the threshold voltage of the first light-emitting element LE1 and the threshold voltage of the second light-emitting element LE2 may be different. For example, the threshold voltage of the second light-emitting element LE2 may be lower than the threshold voltage of the first light-emitting element LE1.

In embodiments, the pixel circuit PXC may not substantially generate a driving current in response to a data signal corresponding to the video data DATA of a black grayscale (e.g., 0 grayscale). In this case, the first light-emitting element LE1 and the second light-emitting element LE2 may not operate, and accordingly, the sub-pixel SPX may not emit light.

The pixel circuit PXC may generate a relatively small driving current in response to a data signal (hereinafter referred to as a “low grayscale data signal”) corresponding to the video data DATA in a low grayscale range (e.g., 1 to 150 grayscales), which is equal to or below a reference value (e.g., a predetermined reference value). In embodiments, during a period in which the sub-pixel SPX is driven by a low grayscale data signal, the voltage, which is lower than the threshold voltage of the first light-emitting element LE1, and which is equal to or higher than the threshold voltage of the second light-emitting element LE2, may be applied between the pixel electrode PXE and the common electrode CE. Accordingly, the first light-emitting element LE1 may maintain an off state, and the second light-emitting element LE2 may emit light. The sub-pixel SPX may emit light at a low luminance corresponding to a low grayscale data signal due to the operation (e.g., light emission) of the second light-emitting element LE2.

In embodiments, the second light-emitting element LE2 may be an element with lower luminous efficiency than the first light-emitting element LE1. Accordingly, in the second light-emitting element LE2, the change in the current density according to the change in the input signal (e.g., low grayscale data signal) may not occur suddenly, but instead may appear relatively gradually. When the sub-pixel SPX is driven with low luminance corresponding to a low grayscale data signal with only the second light-emitting element LE2 while the first light-emitting element LE1 is turned off, the luminance of the sub-pixel SPX may be controlled more precisely or appropriately corresponding to each grayscale according to the low grayscale data signal. Accordingly, the low grayscale expression performance of the sub-pixel SPX may be increased, and the image quality of the display device 10 may be improved.

The pixel circuit PXC may generate a relatively large driving current in response to a data signal (hereinafter referred to as a “high grayscale data signal”) corresponding to the video data DATA in a high grayscale range (e.g., 151 or more grayscales, or 151 to 255 grayscales), which is higher than a reference value. In embodiments, during a period in which the sub-pixel SPX is driven by a high grayscale data signal, the voltage, which is equal to or higher than the threshold voltage of the first light-emitting element LE1, may be applied between the pixel electrode PXE and the common electrode CE. Accordingly, both the first light-emitting element LE1 and the second light-emitting element LE2 may emit light to express a high-luminance grayscale corresponding to the data signal.

In embodiments, the first light-emitting element LE1 may be an element with higher luminous efficiency than the second light-emitting element LE2. Both the first light-emitting element LE1 and the second light-emitting element LE2 may emit light corresponding to the high grayscale data signal, so that, while the driving current flowing through the sub-pixel SPX is appropriately limited, the luminance of the sub-pixel SPX corresponding to each grayscale of the high grayscale data signal may be sufficiently or appropriately secured. Accordingly, the power consumption of the display device 10 may be reduced or improved.

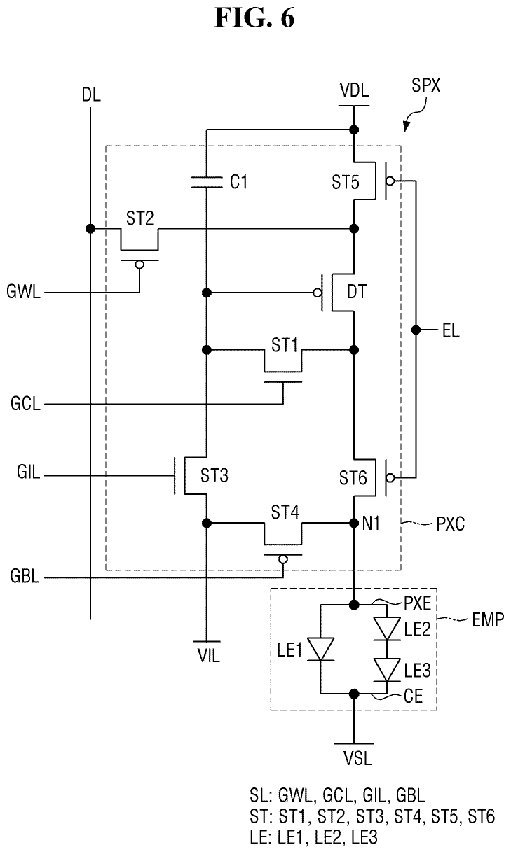

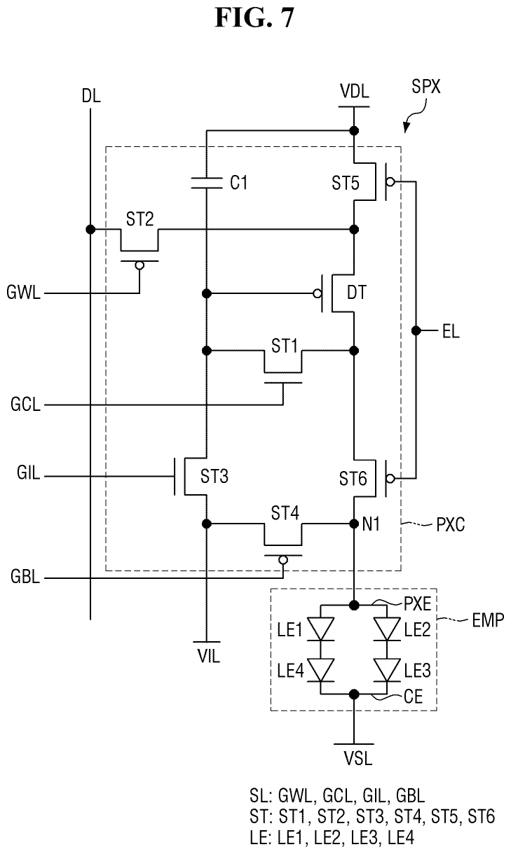

FIG. 6 is a circuit diagram illustrating a sub-pixel according to one or more embodiments. FIG. 7 is a circuit diagram illustrating a sub-pixel according to one or more embodiments. Compared to FIG. 5, FIGS. 6 and 7 illustrate different modified embodiments with respect to the light-emitting unit EMP.

Referring to FIG. 6, the light-emitting unit EMP may further include a third light-emitting element LE3 connected in series with the second light-emitting element LE2. For example, the third light-emitting element LE3 may be connected between the second light-emitting element LE2 and the common electrode CE.

The threshold voltage of the third light-emitting element LE3 may be lower than the threshold voltage of the first light-emitting element LE1. In one or more embodiments, the threshold voltage of the second light-emitting element LE2 and the threshold voltage of the third light-emitting element LE3 may be substantially the same or similar, and the second light-emitting element LE2 and the third light-emitting element LE3 may emit light substantially simultaneously. The third light-emitting element LE3 allows the light-emitting unit EMP to emit light with appropriate or sufficient luminance to express each grayscale even if the driving current is low. Accordingly, the luminance of the sub-pixel SPX may be supplemented or improved, and the light efficiency of the sub-pixel SPX may be increased.

Referring to FIG. 7, the light-emitting unit EMP may further include a fourth light-emitting element LE4 connected in series with the first light-emitting element LE1. For example, the fourth light-emitting element LE4 may be connected between the first light-emitting element LE1 and the common electrode CE.

The threshold voltage of the fourth light-emitting element LE4 may be higher than the threshold voltage of the second light-emitting element LE2 and the threshold voltage of the third light-emitting element LE3. In one or more embodiments, the threshold voltage of the first light-emitting element LE1 and the threshold voltage of the fourth light-emitting element LE4 may be substantially the same or similar, and the first light-emitting element LE1 and the fourth light-emitting element LE4 may emit light substantially simultaneously. The fourth light-emitting element LE4 may improve the luminance and light efficiency of the light-emitting unit EMP and the sub-pixel SPX including the light-emitting unit EMP.

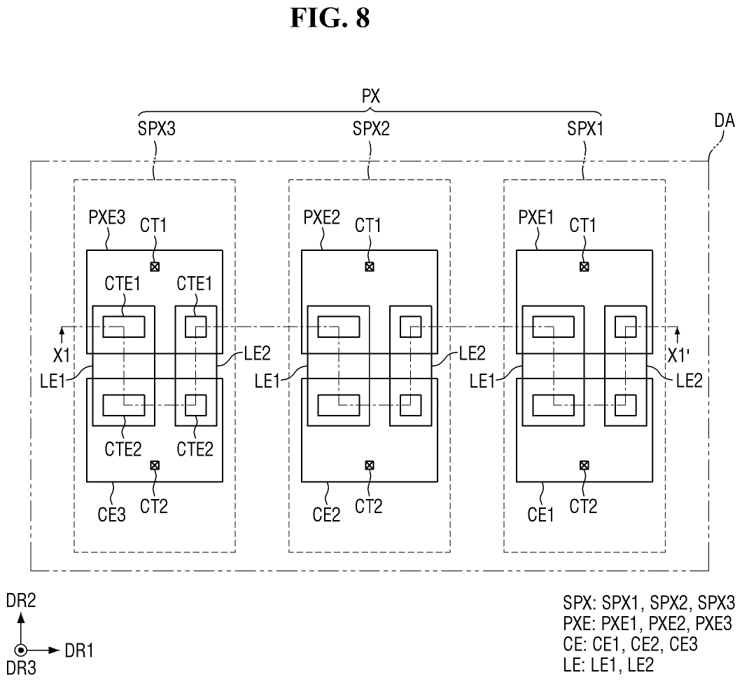

FIG. 8 is a plan view illustrating sub-pixels according to one or more embodiments. For example, FIG. 8 schematically illustrates the light-emitting units EMP of the first sub-pixel SPX1, the second sub-pixel SPX2, and the third sub-pixel SPX3 located in the display area DA.

Referring to FIGS. 1 to 8, each of the unit pixels PX located in the display area DA may include the first sub-pixel SPX1, the second sub-pixel SPX2, and the third sub-pixel SPX3. In one or more embodiments, the first sub-pixel SPX1, the second sub-pixel SPX2, and the third sub-pixel SPX3 constituting one unit pixel PX may be arranged in the first direction DR1, but are not limited thereto. For example, the disposition shape of the sub-pixels SPX may vary depending on the embodiments.

FIG. 8 discloses one or more embodiments in which one first sub-pixel SPX1, one second sub-pixel SPX2, and one third sub-pixel SPX3 constitute one unit pixel PX, but embodiments are not limited thereto. For example, the type, number, ratio, or the like of the sub-pixels SPX constituting each of the unit pixels PX may vary depending on embodiments.

Further, FIG. 8 illustrates that the first sub-pixel SPX1, the second sub-pixel SPX2, and the third sub-pixel SPX3 (or the emission areas of the first sub-pixel SPX1, the second sub-pixel SPX2, and the third sub-pixel SPX3) have substantially the same size and shape, but embodiments are not limited thereto. For example, the size or shape of the sub-pixels SPX may vary depending on embodiments. For example, the size of the sub-pixels SPX may be appropriately adjusted according to the light efficiency of the sub-pixels SPX.

The first sub-pixel SPX1 (also referred to as a “first pixel”) may emit first light, the second sub-pixel SPX2 may emit second light, and the third sub-pixel SPX3 (also referred to as a “second pixel”) may emit third light. In one or more embodiments, the first light may be light of a blue wavelength band, the second light may be light of a green wavelength band, and the third light may be light of a red wavelength band. In one example, the first light, the second light, and the third light may be blue light having a peak wavelength within a range from approximately 440 nm to approximately 480 nm, green light having a peak wavelength within a range from approximately 510 nm to approximately 550 nm, and red light having a peak wavelength within a range from approximately 610 nm to approximately 650 nm, respectively. The color or wavelength band of light emitted from each of the sub-pixels SPX may vary depending on embodiments.

The sub-pixels SPX may include each of the pixel electrodes PXE, the common electrodes CE, and the light-emitting elements LE. For example, the first sub-pixel SPX1 may include a first pixel electrode PXE1, a first common electrode CE1, a first light-emitting element LE1, and a second light-emitting element LE2. The second sub-pixel SPX2 may include a second pixel electrode PXE2, a second common electrode CE2, a first light-emitting element LE1, and a second light-emitting element LE2. The third sub-pixel SPX3 may include a third pixel electrode PXE3, a third common electrode CE3, a first light-emitting element LE1, and a second light-emitting element LE2.

The pixel electrode PXE and the common electrode CE of each of the sub-pixels SPX may be spaced apart from each other in each sub-pixel area. For example, the first pixel electrode PXE1 and the first common electrode CE1 may be spaced apart from each other in the emission area of the first sub-pixel SPX1. The second pixel electrode PXE2 and the second common electrode CE2 may be spaced apart from each other in the emission area of the second sub-pixel SPX2. The third pixel electrode PXE3 and the third common electrode CE3 may be spaced apart from each other in the emission area of the third sub-pixel SPX3.

The respective light-emitting elements LE may be located on or bonded on the pixel electrodes PXE and the common electrodes CE (as used herein, “located on” may mean “above”). For example, the pixel electrodes PXE and the common electrodes CE may be bonding pads that are bonded to the respective light-emitting elements LE. In one or more embodiments, the pixel electrodes PXE and the common electrodes CE may be metal electrodes containing a metal suitable for bonding, but are not limited thereto.

Although FIG. 8 illustrates one or more embodiments in which each of the pixel electrode PXE and the common electrode CE has a quadrilateral planar shape, embodiments are not limited thereto. Further, although FIG. 8 illustrates one or more embodiments in which the respective pixel electrodes PXE and the respective common electrodes CE are formed to have substantially the same size, embodiments are not limited thereto. For example, the shape, size, or the like of the pixel electrode PXE and the common electrode CE located in each of the sub-pixels SPX may be changed depending on embodiments. The sub-pixels SPX may have the pixel electrodes PXE and/or the common electrodes CE of substantially the same size, or the sizes of the pixel electrode PXE and/or the common electrode CE may vary for each of the sub-pixels SPX.

Each of the pixel electrodes PXE may be connected to the pixel circuit PXC of the corresponding sub-pixel SPX through each of first connection holes CT1. For example, the first pixel electrode PXE1 may be connected to the pixel circuit PXC of the first sub-pixel SPX1, the second pixel electrode PXE2 may be connected to the pixel circuit PXC of the second sub-pixel SPX2, and the third pixel electrode PXE3 may be connected to the pixel circuit PXC of the third sub-pixel SPX3.

Each of the common electrodes CE may be connected to the second power line VSL to which the second driving voltage VSS is applied through each of second connection holes CT2. For example, each of the first common electrode CE1, the second common electrode CE2, and the third common electrode CE3 may be connected to the second power line VSL through the second connection hole CT2. Accordingly, the second driving voltage VSS may be applied to the first common electrode CE1, the second common electrode CE2, and the third common electrode CE3.

Although FIG. 8 illustrates one or more embodiments in which the common electrodes CE of the sub-pixels SPX are individually separated, embodiments are not limited thereto. For example, the common electrodes CE located in the plurality of sub-pixels SPX positioned in the display area DA may be formed integrally to form one common electrode CE.

The first light-emitting element LE1 and the second light-emitting element LE2 of each of the sub-pixels SPX may be located or connected in parallel between the pixel electrode PXE and the common electrode CE of the corresponding sub-pixel SPX. For example, the first light-emitting element LE1 and the second light-emitting element LE2 of the first sub-pixel SPX1 may be connected in parallel between the first pixel electrode PXE1 and the first common electrode CE1. The first light-emitting element LE1 and the second light-emitting element LE2 of the second sub-pixel SPX2 may be connected in parallel between the second pixel electrode PXE2 and the second common electrode CE2. The first light-emitting element LE1 and the second light-emitting element LE2 of the third sub-pixel SPX3 may be connected in parallel between the third pixel electrode PXE3 and the third common electrode CE3.

In one or more embodiments, each of the light-emitting elements LE may include a first contact electrode CTE1 connected to each of the pixel electrodes PXE. In one or more embodiments, each of the light-emitting elements LE may further include a second contact electrode CTE2 connected to each of the common electrodes CE.

In embodiments, the first light-emitting element LE1 and the second light-emitting element LE2 of each of the sub-pixels SPX may be the light-emitting elements LE having different characteristics. For example, the threshold voltages of the first light-emitting element LE1 and the second light-emitting element LE2 may be different from each other. In addition, the luminous efficiencies of the first light-emitting element LE1 and the second light-emitting element LE2 may be different from each other. In one or more embodiments, the second light-emitting element LE2 may be an element having a lower threshold voltage and lower luminous efficiency than the first light-emitting element LE1.

In one or more embodiments, the first light-emitting element LE1 and the second light-emitting element LE2 of each of the sub-pixels SPX may have different respective sizes (e.g., different areas and/or volumes). For example, the size of the first light-emitting element LE1 may be larger than the size of the second light-emitting element LE2.

In embodiments, during a period in which each of the sub-pixels SPX is driven at a low luminance by a data signal corresponding to the video data DATA in a low grayscale range equal to or below a reference value, the second light-emitting element LE2 may be caused to emit light with a luminance corresponding to each grayscale by passing a low driving current to the second light-emitting element LE2 having a relatively low luminous efficiency. During a period in which each of the sub-pixels SPX is driven at a high luminance by a data signal corresponding to the video data DATA in a high grayscale range greater than the reference value, the driving current may be appropriately limited by causing the first light-emitting element LE1, which has a relatively high luminous efficiency, to emit light, as well as the second light-emitting element LE2. Accordingly, the sub-pixel SPX may be appropriately caused to emit with a high luminance corresponding to each grayscale while power consumption is reduced or improved.

In one or more embodiments, the light-emitting elements LE located in the sub-pixels SPX may emit light of the same color. As an example, the first light-emitting element LE1 and the second light-emitting element LE2 located in the first sub-pixel SPX1, in the second sub-pixel SPX2, and in the third sub-pixel SPX3 may be first color light-emitting diodes that emit the first light (e.g., light of a blue color). In one or more embodiments, at least some of the sub-pixels SPX (e.g., the second sub-pixel SPX2 and the third sub-pixel SPX3) may further include a light conversion layer that converts light generated from each of the light-emitting elements LE into light of a different wavelength band or a different color.

In one or more other embodiments, the light-emitting elements LE located in the sub-pixels SPX may emit light of different colors. For example, the first light-emitting element LE1 and the second light-emitting element LE2 located in the first sub-pixel SPX1 may be first color light-emitting diodes that emit the first light (e.g., light of the blue color). The first light-emitting element LE1 and the second light-emitting element LE2 located in the second sub-pixel SPX2 may be second color light-emitting diodes that emit the second light (e.g., light of a green color). The first light-emitting element LE1 and the second light-emitting element LE2 located in the third sub-pixel SPX3 may be third color light-emitting diodes that emit the third light (e.g., light of a red color).

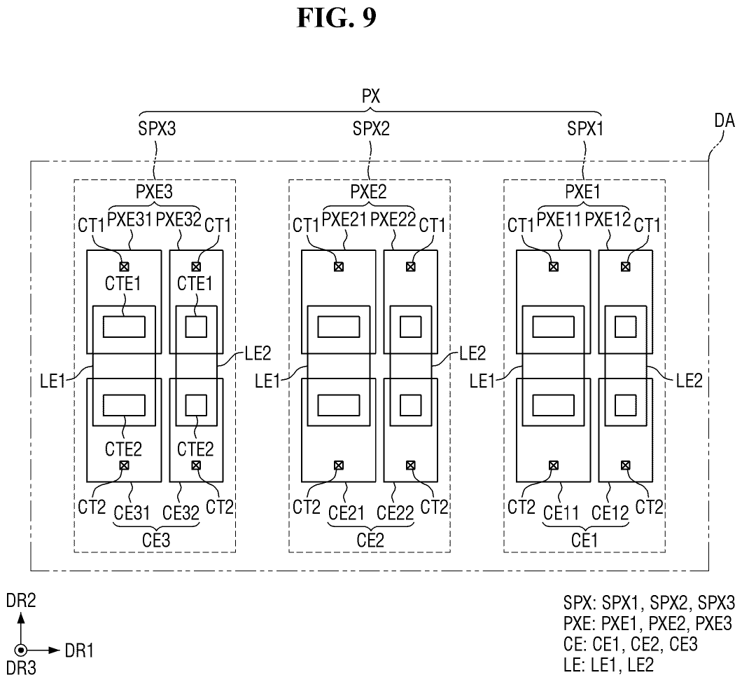

FIG. 9 is a plan view showing sub-pixels according to one or more embodiments. For example, FIG. 9 illustrates the sub-pixels SPX according to one or more embodiments that is different from the one or more embodiments corresponding to FIG. 8 with respect to the pixel electrodes PXE and common electrodes CE.

Referring to FIG. 9, each of the pixel electrodes PXE may include a plurality of sub-pixel electrodes formed of individual patterns separated from each other. For example, the first pixel electrode PXE1 of the first sub-pixel SPX1 may include a first sub-pixel electrode PXE11 and a second sub-pixel electrode PXE12. The first sub-pixel electrode PXE11 and the second sub-pixel electrode PXE12 of the first sub-pixel SPX1 may be electrically connected to each other. For example, the first sub-pixel electrode PXE11 and the second sub-pixel electrode PXE12 of the first sub-pixel SPX1 may be commonly connected to the pixel circuit PXC of the first sub-pixel SPX1 through the respective first connection holes CT1.

The second pixel electrode PXE2 of the second sub-pixel SPX2 may include a first sub-pixel electrode PXE21 and a second sub-pixel electrode PXE22. The first sub-pixel electrode PXE21 and the second sub-pixel electrode PXE22 of the second sub-pixel SPX2 may be electrically connected to each other. For example, the first sub-pixel electrode PXE21 and the second sub-pixel electrode PXE22 of the second sub-pixel SPX2 may be commonly connected to the pixel circuit PXC of the second sub-pixel SPX2 through the respective first connection holes CT1.

The third pixel electrode PXE3 of the third sub-pixel SPX3 may include a first sub-pixel electrode PXE31 and a second sub-pixel electrode PXE32. The first sub-pixel electrode PXE31 and the second sub-pixel electrode PXE32 of the third sub-pixel SPX3 may be electrically connected to each other. For example, the first sub-pixel electrode PXE31 and the second sub-pixel electrode PXE32 of the third sub-pixel SPX3 may be commonly connected to the pixel circuit PXC of the third sub-pixel SPX3 through the respective first connection holes CT1.

In one or more embodiments, each of the common electrodes CE may include a plurality of sub-common electrodes formed of individual patterns separated from each other. For example, the first common electrode CE1 of the first sub-pixel SPX1 may include a first sub-common electrode CE11 and a second sub-common electrode CE12. The first sub-common electrode CE11 and the second sub-common electrode CE12 of the first sub-pixel SPX1 may be electrically connected to each other. For example, the first sub-common electrode CE11 and the second sub-common electrode CE12 of the first sub-pixel SPX1 may be commonly connected to the second power line VSL through the respective second connection holes CT2.

The second common electrode CE2 of the second sub-pixel SPX2 may include a first sub-common electrode CE21 and a second sub-common electrode CE22. The first sub-common electrode CE21 and the second sub-common electrode CE22 of the second sub-pixel SPX2 may be electrically connected to each other. For example, the first sub-common electrode CE21 and the second sub-common electrode CE22 of the second sub-pixel SPX2 may be commonly connected to the second power line VSL through the respective second connection holes CT2.

The third common electrode CE3 of the third sub-pixel SPX3 may include a first sub-common electrode CE31 and a second sub-common electrode CE32. The first sub-common electrode CE31 and the second sub-common electrode CE32 of the third sub-pixel SPX3 may be electrically connected to each other. For example, the first sub-common electrode CE31 and the second sub-common electrode CE32 of the third sub-pixel SPX3 may be commonly connected to the second power line VSL through the respective second connection holes CT2.

Each of the first light-emitting elements LE1 may be located on a first sub-pixel electrode and a first sub-common electrode located in each of the sub-pixels SPX. For example, the first light-emitting element LE1 of the first sub-pixel SPX1 may include a first portion that is located on the first sub-pixel electrode PXE11 of the first sub-pixel SPX1 and that includes the first contact electrode CTE1, and a second portion that extends from the first portion, that is located on the first sub-common electrode CE11 of the first sub-pixel SPX1, and that includes the second contact electrode CTE2.

The first light-emitting element LE1 of the second sub-pixel SPX2 may include a first portion that is located on the first sub-pixel electrode PXE21 of the second sub-pixel SPX2 and that includes the first contact electrode CTE1, and a second portion that extends from the first portion, that is located on the first sub-common electrode CE21 of the second sub-pixel SPX2, and that includes the second contact electrode CTE2.

The first light-emitting element LE1 of the third sub-pixel SPX3 may include a first portion that is located on the first sub-pixel electrode PXE31 of the third sub-pixel SPX3 and that includes the first contact electrode CTE1, and a second portion that extends from the first portion, that is located on the first sub-common electrode CE31 of the third sub-pixel SPX3, and that includes the second contact electrode CTE2.

Each of the second light-emitting elements LE2 may be located on a second sub-pixel electrode and a second sub-common electrode located in each of the sub-pixels SPX. For example, the second light-emitting element LE2 of the first sub-pixel SPX1 may include a first portion that is located on the second sub-pixel electrode PXE12 of the first sub-pixel SPX1 and that includes the first contact electrode CTE1, and a second portion that extends from the first portion, that is located on the second sub-common electrode CE12 of the first sub-pixel SPX1, and that includes the second contact electrode CTE2.

The second light-emitting element LE2 of the second sub-pixel SPX2 may include a first portion that is located on the second sub-pixel electrode PXE22 of the second sub-pixel SPX2 and that includes the first contact electrode CTE1, and a second portion that extends from the first portion, that is located on the second sub-common electrode CE22 of the second sub-pixel SPX2, and that includes the second contact electrode CTE2.

The second light-emitting element LE2 of the third sub-pixel SPX3 may include a first portion that is located on the second sub-pixel electrode PXE32 of the third sub-pixel SPX3 and that includes the first contact electrode CTE1, and a second portion that extends from the first portion, that is located on the second sub-common electrode CE32 of the third sub-pixel SPX3, and that includes the second contact electrode CTE2.

According to embodiments, each of the pixel electrodes PXE is separated into a plurality of sub-pixel electrodes and/or each of the common electrodes CE is separated into a plurality of sub-common electrodes CE, so that damage to elements (e.g., a peripheral insulating layer or conductive pattern, or the like) positioned around the pixel electrodes PXE and the common electrodes CE may be reduced or prevented. For example, in a bonding process or the like that respectively connects the light-emitting elements LE to the pixel electrodes PXE and the common electrodes CE, the pressure applied to the periphery of the pixel electrodes PXE and the common electrodes CE is reduced or relieved, so that damage to elements positioned in the periphery may be reduced or prevented.

Further, according to embodiments, each of the pixel electrodes PXE is separated into a plurality of sub-pixel electrodes and/or each of the common electrodes CE is separated into a plurality of sub-common electrodes CE, so that a repair process for the defective sub-pixel SPX may be performed more conveniently. For example, as each of the pixel electrode PXE and/or the common electrode CE is divided into smaller sized patterns, in a process of repairing the sub-pixel SPX in which a defect has occurred by using a laser cutting method, or the like, scattering of the laser due to the pixel electrode PXE and/or the common electrode CE located in the corresponding sub-pixel SPX may be reduced or prevented, and the area in which repair may be performed may be expanded.

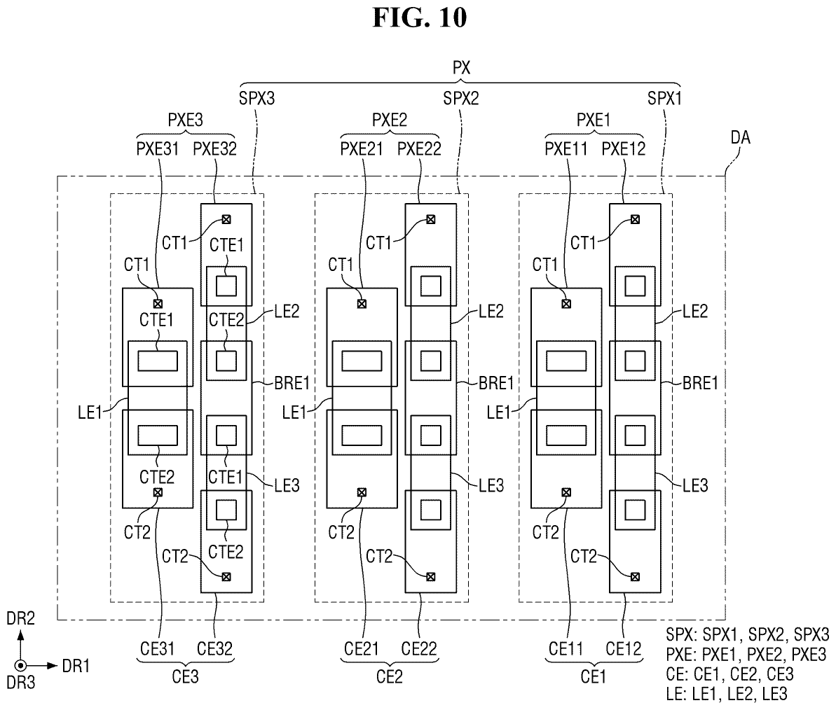

FIG. 10 is a plan view showing sub-pixels according to one or more embodiments. For example, FIG. 10 illustrates one or more embodiments of the sub-pixels SPX further including the third light-emitting element LE3, similar to the one or more embodiments corresponding to FIG. 6.

Referring to FIG. 10, each of the sub-pixels SPX may further include the third light-emitting element LE3 connected in series with the second light-emitting element LE2 between the pixel electrode PXE and the common electrode CE. Further, each of the sub-pixels SPX may further include a first bridge electrode BRE1 connecting the second light-emitting element LE2 to the third light-emitting element LE3.

The second light-emitting element LE2 of each of the sub-pixels SPX may be connected between the pixel electrode PXE and the first bridge electrode BRE1 located in the corresponding sub-pixel SPX. For example, the first contact electrode CTE1 of the second light-emitting element LE2 may be connected to the second sub-pixel electrode PXE12, PXE22, or PXE32, and the second contact electrode CTE2 of the second light-emitting element LE2 may be connected to the first bridge electrode BRE1.

The third light-emitting element LE3 of each of the sub-pixels SPX may be connected between the first bridge electrode BRE1 and the common electrode CE located in the corresponding sub-pixel SPX. For example, the first contact electrode CTE1 of the third light-emitting element LE3 may be connected to the first bridge electrode BRE1, and the second contact electrode CTE2 of the third light-emitting element LE3 may be connected to the second sub-common electrode CE12, CE22 or CE32.

In one or more embodiments, the second light-emitting element LE2 and the third light-emitting element LE3 of each of the sub-pixels SPX may be elements having substantially the same characteristics. For example, the threshold voltages of the second light-emitting element LE2 and the third light-emitting element LE3 of each of the sub-pixels SPX may be substantially the same or similar. In embodiments, the threshold voltages of the second light-emitting element LE2 and the third light-emitting element LE3 of each of the sub-pixels SPX may be lower than the threshold voltage of the first light-emitting element LE1. Further, the luminous efficiencies of the second light-emitting element LE2 and the third light-emitting element LE3 of each of the sub-pixels SPX may be substantially the same or similar. However, the embodiments are not limited thereto. For example, the threshold voltages and/or luminous efficiencies of the second light-emitting element LE2 and the third light-emitting element LE3 may be different.

In one or more embodiments, the second light-emitting element LE2 and the third light-emitting element LE3 of each of the sub-pixels SPX may have substantially the same size. However, the embodiments are not limited thereto. For example, the second light-emitting element LE2 and the third light-emitting element LE3 may have different sizes.

By further locating the third light-emitting element LE3 in the sub-pixel SPX, the luminance (e.g., luminance corresponding to a data signal in a low grayscale range) of the sub-pixel SPX may be supplemented or improved.

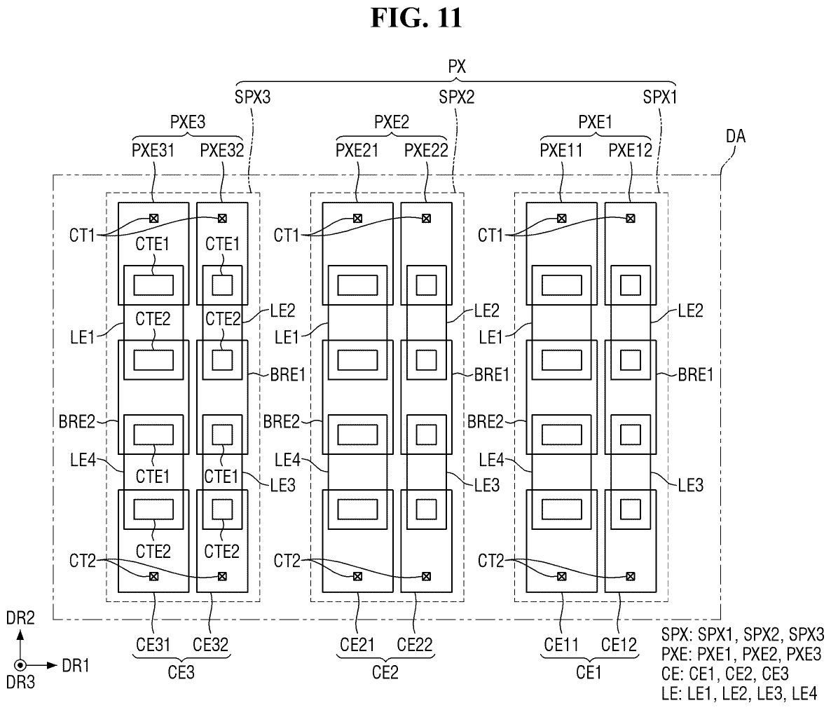

FIG. 11 is a plan view showing sub-pixels according to one or more embodiments. For example, FIG. 11 illustrates one or more embodiments of the sub-pixels SPX further including the fourth light-emitting element LE4, similar to the one or more embodiments corresponding to FIG. 7.

Referring to FIG. 11, each of the sub-pixels SPX may further include the fourth light-emitting element LE4 connected in series with the first light-emitting element LE1 between the pixel electrode PXE and the common electrode CE. Further, each of the sub-pixels SPX may further include a second bridge electrode BRE2 connecting the first light-emitting element LE1 to the fourth light-emitting element LE4.

The first light-emitting element LE1 of each of the sub-pixels SPX may be connected between the pixel electrode PXE and the second bridge electrode BRE2 located in the corresponding sub-pixel SPX. For example, the first contact electrode CTE1 of the first light-emitting element LE1 may be connected to the first sub-pixel electrode PXE11, PXE21, or PXE31, and the second contact electrode CTE2 of the first light-emitting element LE1 may be connected to the second bridge electrode BRE2.

The fourth light-emitting element LE4 of each of the sub-pixels SPX may be connected between the second bridge electrode BRE2 and the common electrode CE located in the corresponding sub-pixel SPX. For example, the first contact electrode CTE1 of the fourth light-emitting element LE4 may be connected to the second bridge electrode BRE2, and the second contact electrode CTE2 of the fourth light-emitting element LE4 may be connected to the first sub-common electrode CE11, CE21 or CE31.

In one or more embodiments, the first light-emitting element LE1 and the fourth light-emitting element LE4 of each of the sub-pixels SPX may be elements having substantially the same characteristics. For example, the threshold voltages of the first light-emitting element LE1 and the fourth light-emitting element LE4 of each of the sub-pixels SPX may be substantially the same or similar. In embodiments, the threshold voltages of the first light-emitting element LE1 and the fourth light-emitting element LE4 of each of the sub-pixels SPX may be higher than the threshold voltages of the second light-emitting element LE2 and the third light-emitting element LE3. Further, the luminous efficiencies of the first light-emitting element LE1 and the fourth light-emitting element LE4 of each of the sub-pixels SPX may be substantially the same or similar. However, the embodiments are not limited thereto. For example, the threshold voltages and/or luminous efficiencies of the first light-emitting element LE1 and the fourth light-emitting element LE4 may be different.

In one or more embodiments, the first light-emitting element LE1 and the fourth light-emitting element LE4 of each of the sub-pixels SPX may have substantially the same size. However, the embodiments are not limited thereto. For example, the first light-emitting element LE1 and the fourth light-emitting element LE4 may have different sizes.

By further disposing the fourth light-emitting element LE4 in the sub-pixel SPX, the luminance (e.g., luminance corresponding to a data signal in a high grayscale range) of the sub-pixel SPX may be supplemented or improved.

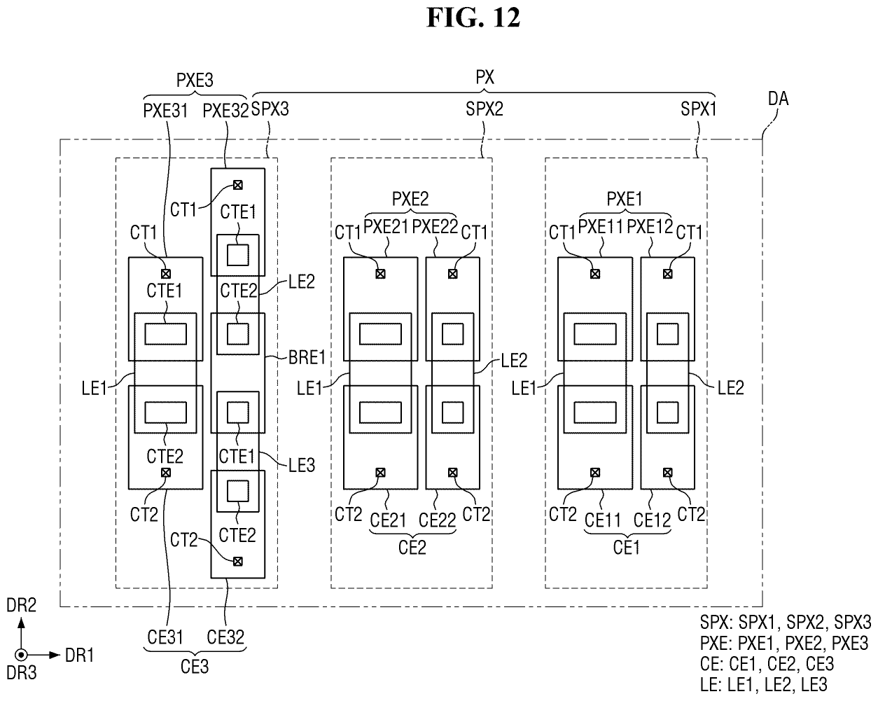

FIG. 12 is a plan view showing sub-pixels according to one or more embodiments. For example, FIG. 12 illustrates one or more embodiments of the unit pixel PX including the sub-pixels SPX of different structures.

Referring to FIG. 12, at least two sub-pixels SPX constituting each of the unit pixels PX may have different structures. For example, the first sub-pixel SPX1 and the third sub-pixel SPX3 may have different structures.

In one or more embodiments, the third sub-pixel SPX3 may include a larger number of the light-emitting elements LE than the first sub-pixel SPX1. As an example, the first sub-pixel SPX1 may include the two light-emitting elements LE including the first light-emitting element LE1 and the second light-emitting element LE2, and the third sub-pixel SPX3 may include the three light-emitting elements LE including the first light-emitting element LE1, the second light-emitting element LE2, and the third light-emitting element LE3.

In one or more embodiments, the second sub-pixel SPX2 may have substantially the same structure as the first sub-pixel SPX1 or the third sub-pixel SPX3. As an example, the second sub-pixel SPX2, similar to the first sub-pixel SPX1, may include the two light-emitting elements LE including the first light-emitting element LE1 and the second light-emitting element LE2. Alternatively, the second sub-pixel SPX2, similar to the third sub-pixel SPX3, may include the three light-emitting elements LE including the first light-emitting element LE1, the second light-emitting element LE2, and the third light-emitting element LE3.

In one or more other embodiments, the second sub-pixel SPX2 may have a different structure from the first sub-pixel SPX1 and the third sub-pixel SPX3. As an example, the first sub-pixel SPX1, the second sub-pixel SPX2, and the third sub-pixel SPX3 may include different numbers of the light-emitting elements LE.

In one or more embodiments, at least two sub-pixels SPX may be formed in different structures in consideration of the light efficiency or luminance or the like of the sub-pixels SPX. For example, when the light efficiency or luminance of the third sub-pixel SPX3 between the first sub-pixel SPX1 and the third sub-pixel SPX3 formed with the same structure is low, a larger number of the light-emitting elements LE are located in the third sub-pixel SPX3, so that the light efficiency or luminance of the third sub-pixel SPX3 may be improved.

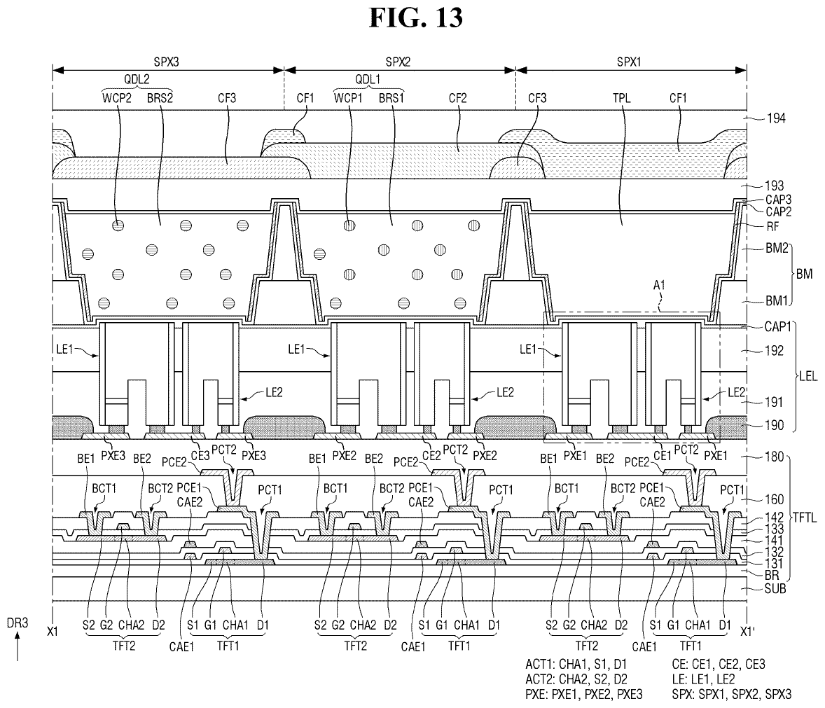

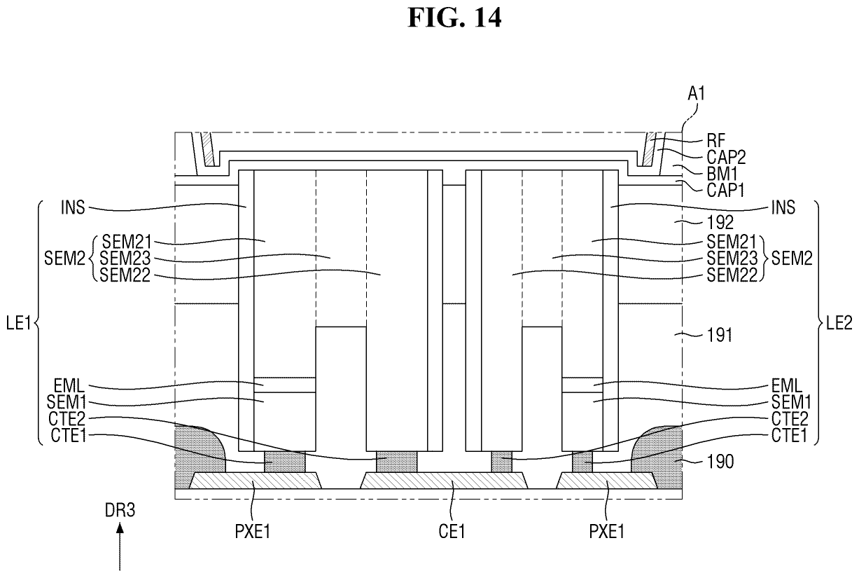

FIG. 13 is a cross-sectional view illustrating a display panel according to one or more embodiments. For example, FIG. 13 illustrates one or more embodiments of a cross section of the display panel 100 taken along the line X1-X1′ of FIG. 8. FIG. 14 is a cross-sectional view showing area A1 of FIG. 13 in detail.

Referring to FIGS. 13 and 14 in addition to FIGS. 1 to 12, the display panel 100 may include the substrate SUB, as well as a thin film transistor layer TFTL (also referred to as a “panel circuit layer”) and a light-emitting element layer LEL located on (e.g., above) the substrate SUB. In one or more embodiments, the display panel 100 may further include light conversion layers, color filters, or the like located on the light-emitting element layer LEL.

The substrate SUB may be formed of an insulating material, such as glass or a polymer resin. When the substrate SUB is made of polymer resin, it may be a flexible substrate that can be stretched. The polymer resin may include acryl resin, epoxy resin, phenolic resin, polyamide resin, or polyimide resin.

The barrier layer BR may be located on the substrate SUB. The barrier layer BR may protect transistors of the thin film transistor layer TFTL and the light-emitting element layer EMTL from moisture permeating through the substrate SUB, which may be susceptible to moisture permeation. The barrier layer BR may be formed as a plurality of inorganic layers that are alternately stacked. For example, the barrier layer BR may be formed of multiple layers in which one or more inorganic layers of a silicon nitride layer, a silicon oxynitride layer, a silicon oxide layer, a titanium oxide layer, and an aluminum oxide layer are alternately stacked.

The first thin film transistor TFT1 may be located on the barrier layer BR. The first thin film transistor TFT1 may be one of the first type transistors (e.g., p-type transistors) among the transistors provided to the pixel circuit PXC of each of the sub-pixels SPX. For example, the first thin film transistor TFT1 may be any one of the fourth transistor ST4 or the sixth transistor ST6 shown in FIG. 5. The first thin film transistor TFT1 may include a first active layer ACT1 and a first gate electrode G1.

The first active layer ACT1 of the first thin film transistor TFT1 may be located on the barrier layer BR. The first active layer ACT1 of the first thin film transistor TFT1 may include polycrystalline silicon, monocrystalline silicon, low-temperature polycrystalline silicon, or amorphous silicon.

The first active layer ACT1 may include a first channel region CHA1, a first source region S1, and a first drain region D1. The first channel region CHA1 may be a region overlapping the first gate electrode G1 in the third direction DR3 that is the thickness direction of the substrate SUB. The first source region S1 may be located on one side of the first channel region CHA1, and the first drain region D1 may be located on the other side of the first channel region CHA1. The first source region S1 and the first drain region D1 may be regions that do not overlap the first gate electrode G1 in the third direction DR3. The first source region S1 and the first drain region D1 may be regions having conductivity by doping a silicon semiconductor with ions.

A first gate-insulating layer 131 may be located on the first channel region CHA1, the first source region S1, and the first drain region D1 of the first thin film transistor TFT1. The first gate-insulating layer 131 may be formed of an inorganic layer, for example, a silicon nitride layer, a silicon oxynitride layer, a silicon oxide layer, a titanium oxide layer, or an aluminum oxide layer.

A first gate metal layer may be located on the first gate-insulating layer 131. The first gate metal layer may include the first gate electrode G1 and the first capacitor electrode CAE1 of the first thin film transistor TFT1. The first gate electrode G1 may overlap the first active layer ACT1 in the third direction DR3. FIG. 13 illustrates that the first gate electrode G1 and the first capacitor electrode CAE1 are spaced apart from each other, but the first gate electrode G1 and the first capacitor electrode CAE1 may be connected to each other. The first gate metal layer may be formed as a single layer or multiple layers made of any one of molybdenum (Mo), aluminum (Al), chromium (Cr), gold (Au), titanium (Ti), nickel (Ni), neodymium (Nd), or copper (Cu) or an alloy thereof.

A second gate-insulating layer 132 may be located on the first gate electrode G1 and the first capacitor electrode CAE1 of the first thin film transistor TFT1. The second gate-insulating layer 132 may be formed of an inorganic layer, for example, a silicon nitride layer, a silicon oxynitride layer, a silicon oxide layer, a titanium oxide layer, or an aluminum oxide layer.

A second gate metal layer may be located on the second gate-insulating layer 132. The second gate metal layer may include a second capacitor electrode CAE2. The second capacitor electrode CAE2 may overlap the first capacitor electrode CAE1 in the third direction DR3. Because the second gate-insulating layer 132 has a dielectric constant (e.g., predetermined dielectric constant), the capacitor (for example, the capacitor C1 in FIG. 5) may be formed by the first capacitor electrode CAE1, the second capacitor electrode CAE2, and the second gate-insulating layer 132 located therebetween. The second gate metal layer may be formed as a single layer or multiple layers made of any one of molybdenum (Mo), aluminum (Al), chromium (Cr), gold (Au), titanium (Ti), nickel (Ni), neodymium (Nd), or copper (Cu) or an alloy thereof.

A first interlayer insulating layer 141 may be located on the second capacitor electrode CAE2. The first interlayer insulating layer 141 may be formed of an inorganic layer, for example, a silicon nitride layer, a silicon oxynitride layer, a silicon oxide layer, a titanium oxide layer, or an aluminum oxide layer.

A second thin film transistor TFT2 may be located on the first interlayer insulating layer 141. The second thin film transistor TFT2 may be one of the second type transistors (e.g., n-type transistors) among the transistors provided to the pixel circuit PXC of each of the sub-pixels SPX. For example, the second thin film transistor TFT2 may be any one of the first transistor ST1 or the third transistor ST3 shown in FIG. 5. The second thin film transistor TFT2 may include the second active layer ACT2 and a second gate electrode G2.

The second active layer ACT2 of the second thin film transistor TFT2 may be located on the first interlayer insulating layer 141. The second active layer ACT2 may include an oxide semiconductor. For example, the second active layer ACT2 may include IGZO (indium (In), gallium (Ga), zinc (Zn) and oxygen (O)), IGZTO (indium (In), gallium (Ga), zinc (Zn), tin (Sn) and oxygen (O)), or IGTO (indium (In), gallium (Ga), tin (Sn), and/or oxygen (O)).

The second active layer ACT2 may include a second channel region CHA2, a second source region S2, and a second drain region D2. The second channel region CHA2 may a region overlapping the second gate electrode G2 in the third direction DR3. The second source region S2 may be located on one side of the second channel region CHA2, and the second drain region D2 may be located on the other side of the second channel region CHA2. The second source region S2 and the second drain region D2 may be regions that do not overlap the second gate electrode G2 in the third direction DR3. The second source region S2 and the second drain region D2 may be regions having conductivity by doping an oxide semiconductor with ions.

A third gate-insulating layer 133 may be located on the second active layer ACT2 of the second thin film transistor TFT2. The third gate-insulating layer 133 may be formed of an inorganic layer, for example, a silicon nitride layer, a silicon oxynitride layer, a silicon oxide layer, a titanium oxide layer, or an aluminum oxide layer.

A third gate metal layer may be located on the third gate-insulating layer 133. The third gate metal layer may include the second gate electrode G2 of the second thin film transistor TFT2. The second gate electrode G2 may overlap the second active layer ACT2 in the third direction DR3. The third gate metal layer GTL3 may be formed as a single layer or multiple layers made of any one of molybdenum (Mo), aluminum (Al), chromium (Cr), gold (Au), titanium (Ti), nickel (Ni), neodymium (Nd), or copper (Cu) or an alloy thereof.

A second interlayer insulating layer 142 may be located on the second gate electrode G2 of the second thin film transistor TFT2. The second interlayer insulating layer 142 may be formed of an inorganic layer, for example, a silicon nitride layer, a silicon oxynitride layer, a silicon oxide layer, a titanium oxide layer, or an aluminum oxide layer.

A first data metal layer (also referred to as a “first source-drain conductive layer”) may be located on the second interlayer insulating layer 142. The first data metal layer may include a first connection electrode PCE1, a second connection electrode BE1, and a third connection electrode BE2. The first connection electrode PCE1 may be connected to the first drain region D of the first active layer ACT1 through a first contact hole PCT1 penetrating the first gate-insulating layer 131, the second gate-insulating layer 132, the first interlayer insulating layer 141, the third gate-insulating layer 133, and the second interlayer insulating layer 142. The second connection electrode BE1 may be connected to the second source region S2 of the second active layer ACT2 through a second contact hole BCT1 penetrating the third gate-insulating layer 133 and the second interlayer insulating layer 142. The third connection electrode BE2 may be connected to the second drain region D2 of the second active layer ACT2 through a third contact hole BCT2 penetrating the third gate-insulating layer 133 and the second interlayer insulating layer 142. The first data metal layer may be formed as a single layer or multiple layers made of any one of molybdenum (Mo), aluminum (Al), chromium (Cr), gold (Au), titanium (Ti), nickel (Ni), neodymium (Nd), or copper (Cu) or an alloy thereof. For example, the first data metal layer may include a first layer made of titanium (Ti), a second layer made of aluminum (Al), and a third layer made of titanium (Ti).

On the first connection electrode PCE1, on the second connection electrode BE1, and on the third connection electrode BE2, a first organic layer 160 for flattening the stepped portion caused by the first thin film transistor TFT1 and the second thin film transistor TFT2 may be located. The first organic layer 160 may be formed of an organic layer, such as acryl resin, epoxy resin, phenolic resin, polyamide resin, polyimide resin, and the like.

A second data metal layer (also referred to as a “second source-drain conductive layer”) may be located on the first organic layer 160. The second data metal layer may include a fourth connection electrode PCE2. The fourth connection electrode PCE2 may be connected to the first connection electrode PCE1 through a fourth contact hole PCT2 penetrating the first organic layer 160. The second data metal layer may be formed as a single layer or multiple layers made of any one of molybdenum (Mo), aluminum (Al), chromium (Cr), gold (Au), titanium (Ti), nickel (Ni), neodymium (Nd), or copper (Cu) or an alloy thereof. For example, the second data metal layer may include a first layer made of titanium (Ti), a second layer made of aluminum (Al), and a third layer made of titanium (Ti).

A second organic layer 180 may be located on the fourth connection electrode PCE2. The second organic layer 180 may be formed of an organic layer, such as acryl resin, epoxy resin, phenolic resin, polyamide resin, polyimide resin and the like.

The light-emitting element layer LEL may be located on the second organic layer 180. The light-emitting element layer LEL may include the pixel electrodes PXE, the common electrodes CE, the light-emitting elements LE, a bank 190, a third organic layer 191, a fourth organic layer 192, and a first capping layer CAP1.

The pixel electrodes PXE and the common electrodes CE may be located on the second organic layer 180. The pixel electrode PXE of each of the sub-pixels SPX may be connected to the fourth connection electrode PCE2 of the corresponding sub-pixel SPX through the first connection hole CT1 (see FIG. 8) penetrating the second organic layer 180. The common electrode CE of each of the sub-pixels SPX may be connected to the second power line VSL (see FIG. 5) through the second connection hole CT2 (see FIG. 8) penetrating the second organic layer 180.

In one or more embodiments, the pixel electrode PXE and the common electrode CE of each of the sub-pixels SPX may not overlap each other in the thickness direction (e.g., the third direction DR3) of the light-emitting elements LE and may overlap different portions of the light-emitting elements LE. For example, the first pixel electrode PXE1 and the first common electrode CE1 may not overlap each other in the thickness direction of the first light-emitting element LE1 and the second light-emitting element LE2 of the first sub-pixel SPX1. Further, a portion of the first light-emitting element LE1 and a portion of the second light-emitting element LE2 may be located on the first pixel electrode PXE1, and another portion of the first light-emitting element LE1 and another portion of the second light-emitting element LE2 may be located on the first common electrode CE1.

The pixel electrodes PXE and the common electrodes CE may be formed as a single layer or multiple layers made of any one of molybdenum (Mo), aluminum (Al), chromium (Cr), gold (Au), titanium (Ti), nickel (Ni), neodymium (Nd), or copper (Cu), or an alloy thereof. For example, to lower the resistance of each of the pixel electrodes PXE and the common electrodes CE, the pixel electrodes PXE and the common electrodes CE may be formed of multiple layers made of copper (Cu) with a low sheet resistance or an alloy made of titanium (Ti), or copper (Cu).

The bank 190 may cover a portion of each of the pixel electrodes PXE and the common electrodes CE. For example, the bank 190 may cover at least one side edge of the pixel electrodes PXE and the common electrodes CE. The bank 190 may not be located on the remaining portions of the pixel electrodes PXE and the common electrodes CE. For example, the bank 190 may not be located on the central portion of each of the pixel electrodes PXE and the common electrodes CE, and on edges in which the pixel electrodes PXE face the common electrodes CE among the edges of the pixel electrodes PXE and the common electrodes CE.

The bank 190 may be formed of an organic layer, such as acryl resin, epoxy resin, phenolic resin, polyamide resin, polyimide resin and the like. The bank 190 may include a light-blocking material to reduce or prevent light of the light-emitting element LE of any one sub-pixel SPX traveling to the neighboring sub-pixel SPX. For example, the bank 190 may contain an organic block pigment or an inorganic black pigment, such as carbon black or the like.

The respective light-emitting elements LE may be located on the pixel electrodes PXE and the common electrodes CE. For example, a portion of the first light-emitting element LE1 and the second light-emitting element LE2 provided to the corresponding sub-pixel SPX may be located on the pixel electrode PXE of each of the sub-pixels SPX, and another portion of the first light-emitting element LE1 and the second light-emitting element LE2 provided in the corresponding sub-pixel SPX may be located on the common electrode CE of each of the sub-pixels SPX. As an example, the first contact electrode CTE1 of each of the first light-emitting element LE1 and the second light-emitting element LE2 provided in the corresponding sub-pixel SPX may be located on the pixel electrode PXE of each of the sub-pixels SPX, and the second contact electrode CTE2 of each of the first light-emitting element LE1 and the second light-emitting element LE2 provided in the corresponding sub-pixel SPX may be located on the common electrode CE of each of the sub-pixels SPX.

In the embodiments of FIGS. 13 and 14, each of the light-emitting elements LE may be a flip-type micro LED. The flip-type micro LED may refer to an LED in which the first contact electrode CTE1 and the second contact electrode CTE2 are formed on one surface (e.g., a bottom surface) of the light-emitting element LE.

In one or more embodiments, each of the light-emitting elements LE may be formed of gallium nitride (GaN) or another inorganic material. In one or more embodiments, each of the light-emitting elements LE may be a micro light-emitting diode having a length in the first direction DR1, a length in the second direction DR2, and a length in the third direction DR3 of several to hundreds of μm, respectively. For example, in each of the light-emitting elements LE, each of the length in the first direction DR1, the length in the second direction DR2, and the length in the third direction DR3 may be about 100 μm or less.

Each of the light-emitting elements LE may be formed by growing on a semiconductor substrate, such as a silicon substrate or sapphire substrate. The light-emitting elements LE may be transferred directly from the semiconductor substrate onto the pixel electrodes PXE and the common electrodes CE of the display panel 100. Alternatively, the light-emitting elements LE may be transferred onto the common electrodes CE and the pixel electrodes PXE of the display panel 100 through an electrostatic method using an electrostatic head or a stamping method using an elastic polymer material, such as PDMS or silicon as a transfer substrate.

Referring to FIG. 14, each of the light-emitting elements LE may include a first semiconductor layer SEM1, a light-emitting layer EML, a second semiconductor layer SEM2, and a passivation layer INS. In one or more embodiments, each of the light-emitting elements LE may further include at least one contact electrode. For example, each of the light-emitting elements LE may further include the first contact electrode CTE1 connected to the first semiconductor layer SEM1, and the second contact electrode CTE2 connected to the second semiconductor layer SEM2.

The first contact electrode CTE1 may be located on the pixel electrode PXE of each of the sub-pixels SPX. For example, the first contact electrode CTE1 may be located between the pixel electrode PXE of each of the sub-pixels SPX and the first semiconductor layer SEM1 of the light-emitting element LE. The first contact electrode CTE1 may connect the first semiconductor layer SEM1 of the light-emitting element LE to the pixel electrode PXE of each of the sub-pixels SPX.

The second contact electrode CTE2 may be located on the common electrode CE of each of the sub-pixels SPX. For example, the second contact electrode CTE2 may be located between the common electrode CE of each of the sub-pixels SPX and the second semiconductor layer SEM2 of the light-emitting element LE. The second contact electrode CTE2 may connect the second semiconductor layer SEM2 of the light-emitting element LE to the common electrode CE of each of the sub-pixels SPX.

The first contact electrode CTE1 and the second contact electrode CTE2 may include metal, metal oxide, or other conductive materials. For example, the first contact electrode CTE1 and the second contact electrode CTE2 may include any one of molybdenum (Mo), aluminum (Al), chromium (Cr), gold (Au), titanium (Ti), nickel (Ni), neodymium (Nd), or copper (Cu).

The first semiconductor layer SEM1 may be located on the first contact electrode CTE1. In one or more embodiments, the first semiconductor layer SEM1 may be made of GaN doped with a first conductivity type dopant (e.g., p-type dopant), such as Mg, Zn, Ca, Se, and/or Ba.

The first semiconductor layer SEM1 may be electrically connected to the pixel electrode PXE of each of the sub-pixels SPX. For example, the first semiconductor layer SEM1 may be electrically connected to the pixel electrode PXE of each of the sub-pixels SPX through the first contact electrode CTE1.

The light-emitting layer EML may be located on the first semiconductor layer SEM1. For example, the light-emitting layer EML may be located between the first semiconductor layer SEM1 and the second semiconductor layer SEM2. The light-emitting layer EML may emit light by recombination of electron-hole pairs according to an electrical signal applied through the first semiconductor layer SEM1 and the second semiconductor layer SEM2.

The light-emitting layer EML may include a material having a single or multiple quantum well structure. When the light-emitting layer EML contains a material having a multiple quantum well structure, the active layer MQW may have the structure in which a plurality of well layers and barrier layers are alternately stacked. In one or more embodiments, the well layer may be formed of InGaN, and the barrier layer may be formed of GaN or AlGaN, but are not limited thereto. Alternatively, the light-emitting layer EML may have a structure in which semiconductor materials having large band gap energy and semiconductor materials having small band gap energy are alternately stacked, and may include other Group III to Group V semiconductor materials according to the wavelength band of the emitted light.

When the light-emitting layer EML includes InGaN, the color of emitted light may vary depending on the content of indium (In). For example, as the content of indium (In) increases, the wavelength band of the light emitted by the light-emitting layer EML may shift to the red wavelength band, and as the content of indium (In) decreases, the wavelength band of the light emitted by the light-emitting layer EML may shift to the blue wavelength band. For example, the light-emitting layer EML of the light-emitting element LE that emits the third light (light in the blue wavelength band) may contain about 10 wt % to about 20 wt % of indium (In).

The second semiconductor layer SEM2 may be located on the light-emitting layer EML. In one or more embodiments, the second semiconductor layer SEM2 may be made of n-GaN doped with a second conductivity type dopant (e.g., n-type dopant), such as Si, Ge, and Sn.

The second semiconductor layer SEM2 may be electrically connected to the common electrode CE of each of the sub-pixels SPX. For example, the second semiconductor layer SEM2 may be electrically connected to the common electrode CE of each of the sub-pixels SPX through the second contact electrode CTE2.

In one or more embodiments, the second semiconductor layer SEM2 may have a larger area than the first semiconductor layer SEM1 and the light-emitting layer EML. The second semiconductor layer SEM2 may include a first portion SEM21 overlapping the first semiconductor layer SEM1 and the light-emitting layer EML, and a second portion SEM22 and a third portion SEM23 that extend from the first portion SEM21 and that do not overlap the first semiconductor layer SEM1 and the light-emitting layer EML.

The second portion SEM22 of the second semiconductor layer SEM2 may be located on the second contact electrode CTE2. The second contact electrode CTE2 may be located between the second portion SEM22 of the second semiconductor layer SEM2 and each of the common electrodes CE.

In one or more embodiments, the second portion SEM22 of the second semiconductor layer SEM2 may have a greater thickness than the remaining portion of the second semiconductor layer SEM2. Accordingly, the light-emitting element LE may be stably located or connected to each of the pixel electrode PXE and the common electrode CE without increasing the thickness of the second contact electrode CTE2. In one or more other embodiments, the second portion SEM22 of the second semiconductor layer SEM2 may have a thickness similar to the remaining portion of the second semiconductor layer SEM2, and the second contact electrode CTE2 may have a greater thickness than the first contact electrode CTE1. Accordingly, the light-emitting element LE may be stably located or connected on each of the pixel electrode PXE and the common electrode CE.

The third portion SEM23 of the second semiconductor layer SEM2 may connect the first portion SEM21 and the second portion SEM22 of the second semiconductor layer SEM2. In one or more embodiments, the third portion SEM23 of the second semiconductor layer SEM2 may have a thickness that is less than the remaining portion of the second semiconductor layer SEM2, but the present disclosure is not limited thereto.

The passivation layer INS may surround the first semiconductor layer SEM1, the light-emitting layer EML, and the second semiconductor layer SEM2. As an example, the passivation layer INS may surround the outer surfaces of the first semiconductor layer SEM1, the light-emitting layer EML, and the second semiconductor layer SEM2.

The passivation layer INS may be a layer for protecting the side surface of the light-emitting element LE. The passivation layer INS may be formed of an inorganic layer, for example, a silicon nitride layer, a silicon oxynitride layer, a silicon oxide layer, a titanium oxide layer, or an aluminum oxide layer.

The third organic layer 191 and the fourth organic layer 192 may be located around the light-emitting elements LE. For example, the third organic layer 191 may be located on at least a portion of the bank 190, the pixel electrodes PXE, and the common electrodes CE, and the fourth organic layer 192 may be located on the third organic layer 191. The third organic layer 191 and the fourth organic layer 192 may cover the side surfaces of the light-emitting elements LE. Each of the third organic layer 191 and the fourth organic layer 192 may be formed of an organic layer, such as acryl resin, epoxy resin, phenolic resin, polyamide resin, polyimide resin, and the like.

The third organic layer 191 and the fourth organic layer 192 may be layers for flattening the stepped portion caused by the light-emitting elements LE. When the third organic layer 191 has a height to cover most of the side surfaces of the light-emitting elements LE, the fourth organic layer 192 may be omitted.

The first capping layer CAP1 may be located on the light-emitting elements LE and the fourth organic layer 192. The first capping layer CAP1 may be formed of an inorganic layer, for example, a silicon nitride layer, a silicon oxynitride layer, a silicon oxide layer, a titanium oxide layer, or an aluminum oxide layer.

Referring to FIG. 13, the light-blocking layer BM, a light-transmitting layer TPL, a first light conversion layer QDL1, and a second light conversion layer QDL2 may be located on the first capping layer CAP1. However, embodiments are not limited thereto, and a third light conversion layer may be located instead of the light-transmitting layer TPL. In this case, the third light conversion layer may include a material that is different from those of the first light conversion layer QDL1 and the second light conversion layer QDL2. For example, the first light conversion layer QDL1 may include quantum dots that convert light in the green wavelength band into light in the red wavelength band, the second light conversion layer QDL2 may include quantum dots that convert light in the blue wavelength band into light in the red wavelength band, and the third light conversion layer may include blue phosphors. Further, each of the first light conversion layer QDL1, the second light conversion layer QDL2, and the third light conversion layer may include a light dispersing agent, such as titanium dioxide (TiO₂) as well as quantum dots. In this case, the number of titanium dioxide (TiO₂) particles in the third light conversion layer may be larger than the number of titanium dioxide (TiO₂) particles in the first light conversion layer QDL1 or than the number of titanium dioxide (TiO₂) particles in the second light conversion layer QDL2.

The light-transmitting layer TPL, the first light conversion layer QDL1, and the second light conversion layer QDL2 may be formed in each emission area partitioned by the light-blocking layer BM. For example, the light-transmitting layer TPL may be located on the first capping layer CAP1 in the first sub-pixel SPX1, the first light conversion layer QDL1 may be located on the first capping layer CAP1 in the second sub-pixel SPX2, and the second light conversion layer QDL2 may be located on the first capping layer CAP1 in the third sub-pixel SPX3. The light-blocking layer BM may overlap the bank 190 in the third direction DR3, and may not overlap the light-emitting elements LE.

The light-transmitting layer TPL may include a light-transmissive organic material. For example, the light-transmitting layer TPL may include epoxy resin, acrylic resin, cardo resin, imide resin, or the like.

The first light conversion layer QDL1 may convert a part of the first light (light in the blue wavelength band) incident from the light-emitting element LE into the second light (light in the green wavelength band). The first light conversion layer QDL1 may include a first base resin BRS1 and a first wavelength conversion particle WCP1. The first base resin BRS1 may include a light-transmissive organic material. For example, the first base resin BRS1 may contain epoxy resin, acrylic resin, cardo resin, or imide resin. The first wavelength conversion particle WCP1 may convert a part of the first light (light in the blue wavelength band) incident from the light-emitting element LE into the second light (light in the green wavelength band). The first wavelength conversion particle WCP1 may be a quantum dot (QD), a quantum rod, a fluorescent material, or a phosphorescent material. The first light conversion layer QDL1 may further include a light diffusion agent, such as titanium dioxide (TiO₂).

The second light conversion layer QDL2 may convert a part of the first light (light in the blue wavelength band) incident from the light-emitting element LE into the third light (light in the red wavelength band). The second light conversion layer QDL2 may include a second base resin BRS2 and second wavelength conversion particles WCP2. The second base resin BRS2 may contain a light-transmissive organic material. For example, the second base resin BRS2 may contain epoxy resin, acrylic resin, cardo resin, or imide resin. The second wavelength conversion particle WCP2 may convert a part of the first light (light in the blue wavelength band) incident from the light-emitting element LE into the third light (light in the red wavelength band). The second wavelength conversion particle WCP2 may be a quantum dot (QD), a quantum rod, a fluorescent material, or a phosphorescent material. The second light conversion layer QDL2 may further include a light diffusion agent, such as titanium dioxide (TiO₂).

The light-blocking layer BM may include a first light-blocking layer BM1 and a second light-blocking layer BM2 that are sequentially stacked. The length of the first light-blocking layer BM1 in the first direction DR1 or the length of the first light-blocking layer BM1 in the second direction DR2 may be greater than the length of the second light-blocking layer BM2 in the first direction DR1 or the length of the second light-blocking layer BM2 in the second direction DR2. The length (or height) of the first light-blocking layer BM1 in the third direction DR3 may be greater than the length (or height) of the second light-blocking layer BM2 in the third direction DR3. The first light-blocking layer BM1 and the second light-blocking layer BM2 may include an organic layer, such as acryl resin, epoxy resin, phenolic resin, polyamide resin, polyimide resin and the like. The first light-blocking layer BM1 and the second light-blocking layer BM2 may further include a dye or pigment having light-blocking properties. For example, the first light-blocking layer BM1 and the second light-blocking layer BM2 may contain an organic block pigment or an inorganic black pigment, such as carbon black or the like.

The second capping layer CAP2 may be located on the first capping layer CAP1 and the light-blocking layer BM. The second capping layer CAP2 may be located on the side and top surfaces of the light-blocking layer BM. That is, the second capping layer CAP2 may be located on the side surface of the first light-blocking layer BM1, and the side and top surfaces of the second light-blocking layer BM2. The second capping layer CAP2 serves to protect the first wavelength conversion particles WCP1 of the first light conversion layer QDL1 and the second wavelength conversion particles WCP2 of the second light conversion layer QDL2 from moisture permeation, and thus may be located to surround the upper portion, the lower portion, and the side surface(s) of the first light conversion layer QDL1 and the second light conversion layer QDL2.

A reflection layer RF may be located between the light-blocking layer BM and the light-transmitting layer TPL, between the light-blocking layer BM and the first light conversion layer QDL1, and between the light-blocking layer BM and the second light conversion layer QDL2. The reflection layer RF may be located on the second capping layer CAP2 located on the side surface of the first light-blocking layer BM1 and the side surface of the second light-blocking layer BM2. The reflection layer RF serves to reflect light traveling in the lateral direction from the first light conversion layer QDL1, the second light conversion layer QDL2, and the light-transmitting layer TPL.

The reflection layer RF may include a metal material having high reflectivity, such as aluminum (Al). The thickness of the reflection layer RF may be approximately 0.1 μm.

Alternatively, the reflection layer RF may include M (M being an integer of 2 or more) pairs of first layers and second layers having different respective refractive indices to serve as a distributed Bragg reflector (DBR). In this case, M first layers and M second layers may be located alternately. The first layer and the second layer may be formed of an inorganic layer, for example, a silicon nitride layer, a silicon oxynitride layer, a silicon oxide layer, a titanium oxide layer, or an aluminum oxide layer.

The third capping layer CAP3 may be located on the second capping layer CAP2, the light-transmitting layer TPL, the first light conversion layer QDL1, and the second light conversion layer QDL2. The third capping layer CAP3 may be formed of an inorganic layer, for example, a silicon nitride layer, a silicon oxynitride layer, a silicon oxide layer, a titanium oxide layer, or an aluminum oxide layer. The light-transmitting layer TPL, the first light conversion layer QDL1, and the second light conversion layer QDL2 may be encapsulated by the first capping layer CAP1, the second capping layer CAP2, and the third capping layer CAP3. The refractive index of the third capping layer CAP3 may be lower than the refractive index of the second capping layer CAP2. Further, the refractive index of the third capping layer CAP3 may be lower than the refractive index of a fifth organic layer 193.

The fifth organic layer 193 may be located on the second capping layer CAP2. The fifth organic layer 193 may be formed of acryl resin, epoxy resin, phenolic resin, polyamide resin, polyimide resin or the like.

Color filters may be located on the fifth organic layer 193. The color filters may include first color filters CF1, second color filters CF2, and third color filters CF3. However, the embodiments are not limited thereto. For example, when the light-emitting elements LE of the first sub-pixel SPX1 emit light of the first color, the light-emitting elements LE of the second sub-pixel SPX2 emit light of the second color, and the light-emitting elements LE of the third sub-pixel SPX3 emit light of the third color, then the light-transmitting layer TPL, the first light conversion layer QDL1, the second light conversion layer QDL2, and the light-blocking layer BM may be omitted. Further, in this case, the fifth organic layer 193 may be located on the first capping layer CAP1, and color filters may be located on the fifth organic layer 193, or the color filters may be omitted.

The first color filter CF1 may be located in the first sub-pixel SPX1. The first color filter CF1 may transmit first light (e.g., light in a blue wavelength band). For example, the first color filter CF1 may transmit the first light emitted from the light-emitting element LE and passing through the light-transmitting layer TPL. Accordingly, the first sub-pixel SPX1 may emit the first light.

The second color filter CF2 may be located in the second sub-pixel SPX2. The second color filter CF2 may transmit the second light (e.g., light in a green wavelength band) and may absorb or block the first light. For example, the second color filter CF2 may transmit the second light obtained by the conversion by the first light conversion layer QDL1 of the first light emitted from the light-emitting element LE, and may absorb or block the first light that is not converted by the first light conversion layer QDL1. Accordingly, the second sub-pixel SPX2 may emit the second light.

The third color filter CF3 may be located in the third sub-pixel SPX3. The third color filter CF3 may transmit the third light (e.g., light in a red wavelength band) and may absorb or block the first light. For example, the third color filter CF3 may transmit the third light obtained by the conversion by the second light conversion layer QDL2 of the first light emitted from the light-emitting element LE, and may absorb or block the first light that is not converted by the first light conversion layer QDL1. Accordingly, the third sub-pixel SPX3 may emit the third light.

Each of the first, second, and third color filters CF1, CF2, and CF3 may block external light incident from the outside. For example, the third color filter CF3 blocks the first light, which is light in the blue wavelength band, and the second light, which is light in the green wavelength band, incident from the outside, so that the purity (color purity) of the color corresponding to the third light that is light in the red wavelength band may be increased.

The first color filter CF1, the second color filter CF2, and the third color filter CF3 may overlap the bank 190 and the light-blocking layer BM in the third direction DR3.

A sixth organic layer 194 for planarization may be located on the first, second and third color filters CF1, CF2, and CF3. The sixth organic layer 194 may be formed of acryl resin, epoxy resin, phenolic resin, polyamide resin, polyimide resin, or the like.

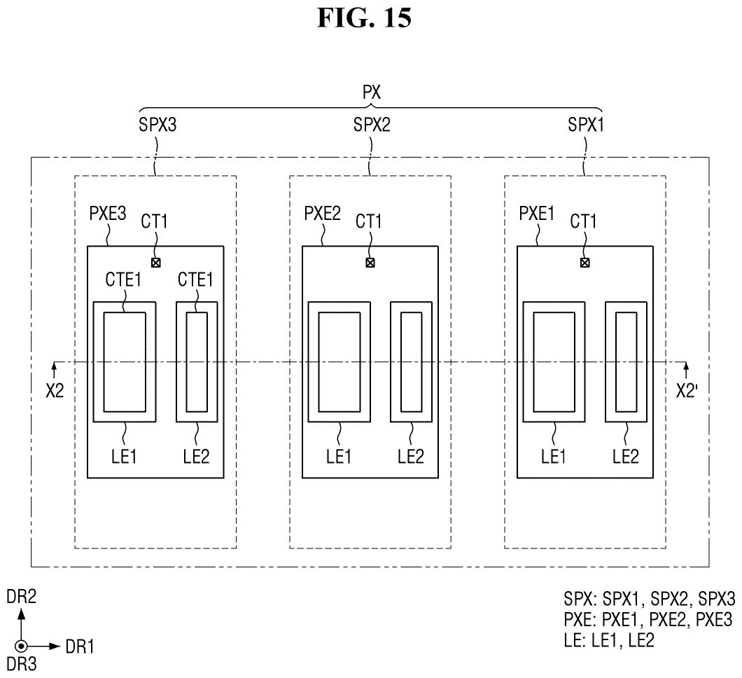

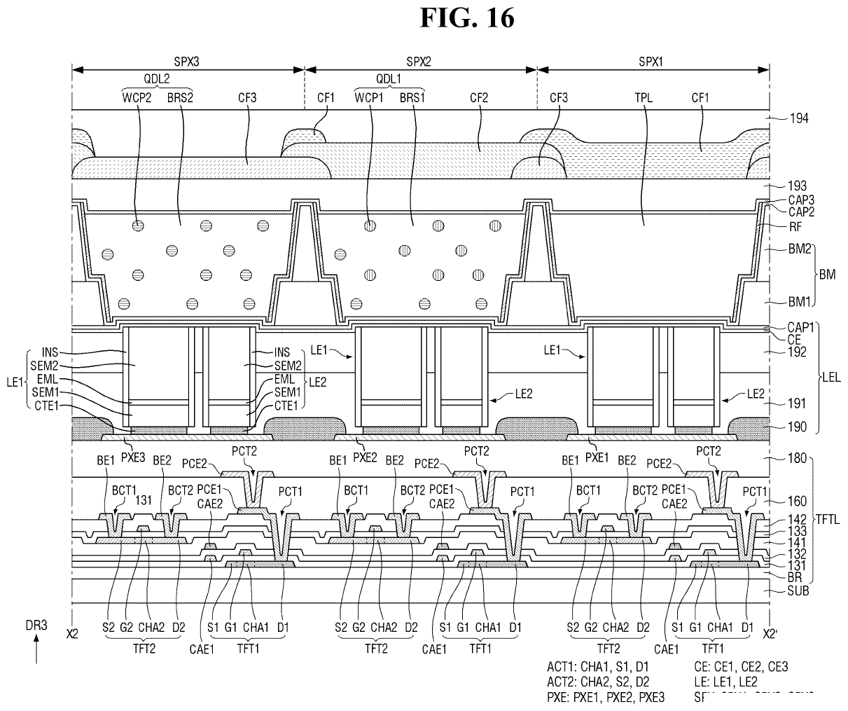

FIG. 15 is a plan view showing sub-pixels according to one or more embodiments. FIG. 16 is a cross-sectional view illustrating a display panel according to one or more embodiments. For example, FIG. 16 illustrates one or more embodiments of a cross section of the display panel 100 taken along the line X2-X2′ of FIG. 15. FIGS. 15 and 16 illustrate one or more embodiments that is different from the embodiments of FIGS. 8, 13, and 14 with respect to the pixel electrodes PXE, the common electrode CE, and the light-emitting elements LE.

Referring to FIGS. 15 and 16 in addition to FIGS. 1 to 14, the pixel electrode PXE and the common electrode CE of each of the sub-pixels SPX may overlap each other. For example, the pixel electrode PXE and the common electrode CE may overlap each other in the thickness direction (e.g., the third direction DR3) of the light-emitting elements LE. In one or more embodiments, the pixel electrode PXE may be formed individually for each of the sub-pixels SPX, and the common electrode CE may be formed as one electrode shared by the plurality of sub-pixels SPX. For example, the first common electrode CE1, the second common electrode CE2, and the third common electrode CE3 illustrated in FIGS. 8 to 14 may be integrated into one common electrode CE. The edge of each of the pixel electrodes PXE may be covered by the bank 190.

The light-emitting elements LE of each of the sub-pixels SPX may be located between the pixel electrode PXE and the common electrode CE of the corresponding sub-pixel SPX. For example, the light-emitting elements LE of each of the sub-pixels SPX may be located on the pixel electrode PXE of the corresponding sub-pixel SPX, and may be covered with the common electrode CE. For example, the first light-emitting element LE1 and the second light-emitting element LE2 of the first sub-pixel SPX1 may be located on the first pixel electrode PXE1. The first light-emitting element LE1 and the second light-emitting element LE2 of the second sub-pixel SPX2 may be located on the second pixel electrode PXE2. The first light-emitting element LE1 and the second light-emitting element LE2 of the third sub-pixel SPX3 may be located on the third pixel electrode PXE3.

Each of the light-emitting elements LE may include the first semiconductor layer SEM1, the light-emitting layer EML, and the second semiconductor layer SEM2 sequentially located along the third direction DR3. For example, each of the light-emitting elements LE may be a vertical type micro LED extending in the third direction DR3. The vertical type micro LED may refer to an LED having a structure in which the first semiconductor layer SEM1, the light-emitting layer EML, and the second semiconductor layer SEM2 are sequentially located in the third direction DR3 that is a perpendicular direction.

In one or more embodiments, the first semiconductor layer SEM1, the light-emitting layer EML, and the second semiconductor layer SEM2 of each of the light-emitting elements LE may have substantially the same or similar areas, but are not limited thereto.

Each of the light-emitting elements LE may further include the passivation layer INS. The passivation layer INS may surround the side surfaces of the first semiconductor layer SEM1, the light-emitting layer EML, and the second semiconductor layer SEM2.

In one or more embodiments, each of the light-emitting elements LE may include the first contact electrode CTE1 connected to each of the pixel electrodes PXE. The first semiconductor layer SEM1, the light-emitting layer EML, and the second semiconductor layer SEM2 of each of the light-emitting elements LE may be sequentially located on the first contact electrode CTE1.

In one or more embodiments, each of the light-emitting elements LE may not include the second contact electrode CTE2 described in the previous embodiments. For example, the second semiconductor layer SEM2 may be directly connected to the common electrode CE.

In one or more embodiments, the common electrode CE may be located entirely on the light-emitting elements LE of the sub-pixels SPX. As an example, the common electrode CE may be located on the fourth organic layer 192 and the light-emitting elements LE of the sub-pixels SPX positioned in the display area DA, and may be formed entirely in the display area DA. In one or more embodiments, the common electrode CE may be located directly on the second semiconductor layers SEM2 of the light-emitting elements LE.

The common electrode CE may be made of a transparent conductive material (TCO), such as indium tin oxide (ITO) and indium zinc oxide (IZO) capable of transmitting light. The common electrode CE may be covered with the first capping layer CAP1.

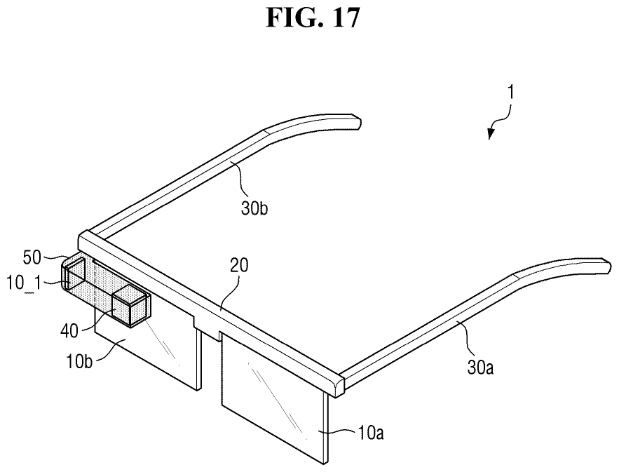

FIG. 17 is a diagram illustrating a virtual reality device including a display device according to one or more embodiments.

Referring to FIG. 17, a virtual reality device 1 according to one or more embodiments may be a glass-type device. The virtual reality device 1 according to one or more embodiments may include a display device 10_1, a left lens 10a, a right lens 10b, a support frame 20, temples 30a and 30b, a reflection member 40, and a display device housing 50.

Although FIG. 17 illustrates the virtual reality device 1 including the temples 30a and 30b, the virtual reality device 1 according to one or more embodiments may be applied to a head-mounted display including a head-mounted band that may be worn on a head, instead of the temples 30a and 30b. For example, the virtual reality device 1 according to one or more embodiments is not limited to the form shown in FIG. 17, and may be applied in various forms to various other electronic devices.

The display device housing 50 may include the display device 10_1 and the reflection member 40. The image displayed on the display device 10_1 may be reflected by the reflection member 40, and may be provided to a user's right eye through the right lens 10b. Accordingly, the user can view the virtual reality image displayed on the display device 10_1 through the right eye.

Although FIG. 17 illustrates that the display device housing 50 is located at the right end of the support frame 20, the embodiments are not limited thereto. For example, the display device housing 50 may be located at the left end of the support frame 20, and in this case, the image displayed on the display device 10_1 may be reflected by the reflection member 40 and may be provided to a user's left eye through the left lens 10a. Accordingly, the user can view the virtual reality image displayed on the display device 10_1 through the left eye. Alternatively, the display device housing 50 may be located at both the left end and the right end of the support frame 20. In that case, the user can view the virtual reality image displayed on the display device 10_1 through both the left eye and the right eye.

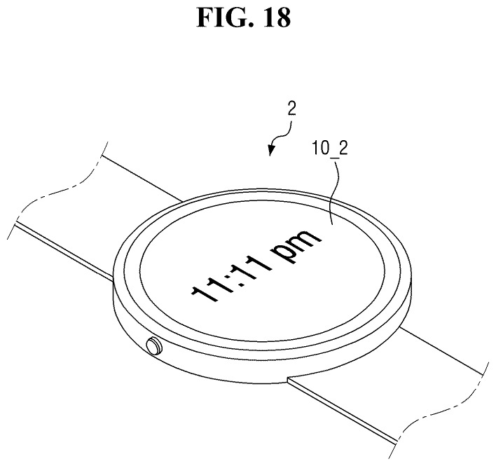

FIG. 18 is a diagram illustrating a smart device including a display device according to one or more embodiments.

Referring to FIG. 18, a display device 10_2 according to one or more embodiments may be applied to a smart watch 2 that is one of the smart devices. The planar shape of a clock display unit of the smart watch 2 may follow the planar shape of the display device 10_2. For example, when the display device 10_2 according to one or more embodiments has a planar shape, such as a circular shape or an elliptical shape, the clock display unit of the smart watch 2 may have a planar shape, such as a circular shape or an elliptical shape. Alternatively, when the display device 10_2 according to one or more embodiments has a quadrilateral planar shape, the clock display unit of the smart watch 2 may have a quadrilateral planar shape. However, the embodiments are not limited thereto, and the clock display unit of the smart watch 2 may not follow the planar shape of the display device 10_2.

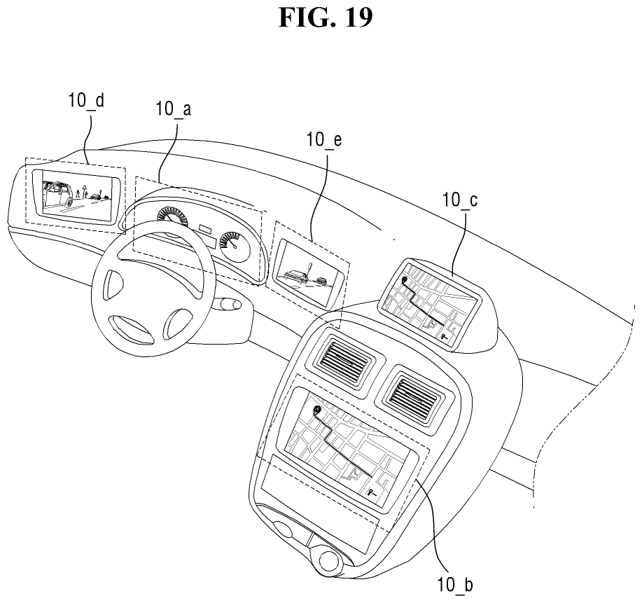

FIG. 19 is a diagram illustrating a dashboard of an automobile and a center fascia including display devices according to one or more embodiments. FIG. 19 illustrates a vehicle to which display devices 10_a, 10_b, 10_c, 10_d, and 10_e according to one or more embodiments are applied.

Referring to FIG. 19, the display devices 10_a, 10_b, and 10_c according to one or more embodiments may be applied to the dashboard of the automobile, the center fascia of the automobile, or the center information display (CID) of the dashboard of the automobile. Alternatively, the display devices 10_d, and 10_e according to one or more embodiments may be applied to a room mirror display instead of side mirrors of the automobile.

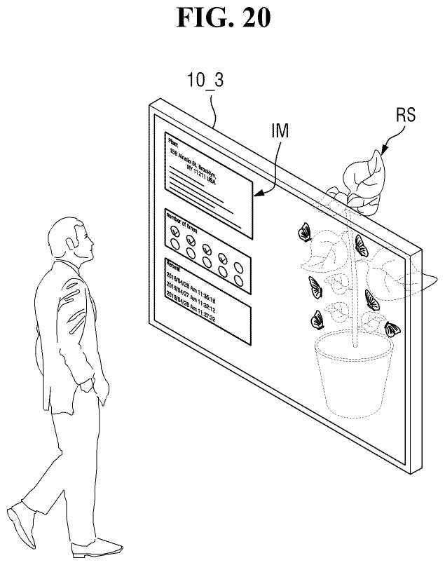

FIG. 20 is a diagram illustrating a transparent display device including a display device according to one or more embodiments.

Referring to FIG. 20, a display device 10_3 according to one or more embodiments may be applied to the transparent display device. The transparent display device may display an image IM, and also may transmit light. Accordingly, a user located in front of the transparent display device can view an object RS or a background located behind the transparent display device as well as the image IM displayed on the display device 10_3. When the display device 10_3 is applied to a transparent display device, the display panel 100 may include a light transmission portion capable of transmitting light, or may be formed on a substrate member made of a material capable of transmitting light.

In concluding the detailed description, those skilled in the art will appreciate that many variations and modifications can be made to the embodiments without substantially departing from the aspects of the present disclosure. Therefore, the disclosed embodiments of the present disclosure are used in a generic and descriptive sense only and not for purposes of limitation.

What is claimed is:

1. A display device comprising:
a first pixel in a display area, and comprising:
a first pixel electrode;
a first common electrode spaced apart from the first pixel electrode;
a first light-emitting element connected between the first pixel electrode and the first common electrode; and
a second light-emitting element connected in parallel with the first light-emitting element between the first pixel electrode and the first common electrode, and having a threshold voltage that is lower than a threshold voltage of the first light-emitting element.

2. The display device of claim 1, wherein a size of the first light-emitting element is different from a size of the second light-emitting element.

3. The display device of claim 2, wherein the size of the first light-emitting element is larger than the size of the second light-emitting element.

4. The display device of claim 1, wherein a luminous efficiency of the first light-emitting element is higher than a luminous efficiency of the second light-emitting element.

5. The display device of claim 1, wherein the first pixel electrode and the first common electrode do not overlap each other in a thickness direction of the first light-emitting element and the second light-emitting element,
wherein a portion of the first light-emitting element and a portion of the second light-emitting element are above the first pixel electrode, and
wherein another portion of the first light-emitting element and another portion of the second light-emitting element are above the first common electrode.

6. The display device of claim 1, wherein the first pixel electrode and the first common electrode do not overlap each other in a thickness direction of the first light-emitting element and the second light-emitting element,
wherein the first light-emitting element and the second light-emitting element are above the first pixel electrode, and
wherein the first common electrode is above the first light-emitting element and the second light-emitting element.

7. The display device of claim 1, wherein the first pixel electrode comprises a first sub-pixel electrode and a second sub-pixel electrode separated from each other and electrically connected to each other.

8. The display device of claim 7, wherein the first light-emitting element and the second light-emitting element are above the first sub-pixel electrode and the second sub-pixel electrode, respectively.

9. The display device of claim 7, wherein the first common electrode comprises a first sub-common electrode and a second sub-common electrode separated from each other and electrically connected to each other.

10. The display device of claim 9, wherein the first light-emitting element comprises a first portion above the first sub-pixel electrode, and a second portion extending from the first portion and above the first sub-common electrode, and
wherein the second light-emitting element comprises a first portion above the second sub-pixel electrode, and a second portion extending from the first portion and above the second sub-common electrode.

11. The display device of claim 1, wherein the first light-emitting element and the second light-emitting element comprise:
a first contact electrode above the first pixel electrode;
a first semiconductor layer above the first contact electrode;
a light-emitting layer above the first semiconductor layer; and
a second semiconductor layer above the light-emitting layer, and electrically connected to the first common electrode.

12. The display device of claim 11, wherein the first light-emitting element and the second light-emitting element further comprise a second contact electrode between the second semiconductor layer and the first common electrode.

13. The display device of claim 1, wherein the first pixel further comprises a third light-emitting element connected in series with the second light-emitting element between the first pixel electrode and the first common electrode, and
wherein a threshold voltage of the third light-emitting element is lower than the threshold voltage of the first light-emitting element.

14. The display device of claim 13, wherein the threshold voltage of the third light-emitting element is equal to the threshold voltage of the second light-emitting element.

15. The display device of claim 1, wherein the first pixel further comprises a fourth light-emitting element connected in series with the first light-emitting element between the first pixel electrode and the first common electrode, and
wherein a threshold voltage of the fourth light-emitting element is higher than the threshold voltage of the second light-emitting element.

16. The display device of claim 15, wherein the threshold voltage of the fourth light-emitting element is equal to the threshold voltage of the first light-emitting element.

17. The display device of claim 1, further comprising a second pixel in the display area and comprising more light-emitting elements than the first pixel,
wherein two of the light-emitting elements of the second pixel are connected in parallel and have different respective threshold voltages.

18. The display device of claim 17, wherein the first pixel and the second pixel are configured to emit light of different respective colors.

19. A pixel comprising:
a pixel electrode;
a common electrode spaced apart from the pixel electrode;
a first light-emitting element connected between the pixel electrode and the common electrode; and
a second light-emitting element connected in parallel with the first light-emitting element between the pixel electrode and the common electrode, and having a threshold voltage that is lower than a threshold voltage of the first light-emitting element.

20. The pixel of claim 19, further comprising a third light-emitting element connected in series with the second light-emitting element between the pixel electrode and the common electrode,
wherein a threshold voltage of the third light-emitting element is lower than the threshold voltage of the first light-emitting element.
